(19) United States
(12) Patent Application Publication
(10) Pub. No.: US 2026/0215090 A1
(43) Pub. Date: Jul. 23, 2026

(54) DISPLAY DEVICE AND ELECTRONIC DEVICE INCLUDING THE SAME

(71) Applicant: Samsung Display Co., Ltd., Yongin-si (KR)

(72) Inventors: Yonghee LEE, Yongin-si (KR); Kyung-Bae KIM, Yongin-si (KR); Dongwoo KIM, Yongin-si (KR); Yeonkyung KIM, Yongin-si (KR)

(73) Assignee: Samsung Display Co., Ltd., Yongin-si (KR)

(21) Appl. No.: 19/361,845

(22) Filed: Oct. 17, 2025

(30) Foreign Application Priority Data
Jan. 17, 2025 (KR) 10-2025-0007389

(51) Int. Cl. H10K 59/121; G09G 3/20; G09G 3/3233

(52) U.S. Cl. CPC H10K 59/1213; G09G 3/2092; G09G 3/3233; G09G 2300/0452; G09G 2300/0819; G09G 2300/0852; G09G 2300/0861

(57) ABSTRACT

A display device includes: a substrate including first and second pixel circuit areas, wherein the second pixel circuit area is adjacent to the first pixel circuit area in a first direction; a first driving transistor of a first pixel driving circuit part, wherein the first driving transistor is provided in both of the first and second pixel circuit areas; a second driving transistor of a second pixel driving circuit part, wherein the second driving transistor provided in both of the first and second pixel circuit areas, and is adjacent to the first driving transistor in a second direction intersecting the first direction; a first light-emitting element connected to the first pixel driving circuit part and provided in a first light-emitting area; and a second light-emitting element connected to the second pixel driving circuit part and provided in a second light-emitting area.

### CROSS-REFERENCE TO RELATED APPLICATION

This application claims priority to Korean Patent Application No. 10-2025-0007389, filed on January 17, 2025 in the Korean Intellectual Property Office, the disclosure of which is incorporated by reference herein in its entirety.

### BACKGROUND

### Technical Field

The present disclosure relates to a display device and an electronic device including the same. More particularly, embodiments relate to a display device which provides visual information and an electronic device including the same.

### Description of Related Art

As information technology develops, the importance of display devices, which are communication media between users and information, is being highlighted. Accordingly, the use of display devices such as a liquid crystal display device, an organic light emitting display device, a plasma display device, and the like is increasing.

Recently, display devices using high-resolution micro OLEDs (organic light emitting diodes) are being manufactured. The high-resolution micro OLEDs may be OLEDos (organic light emitting diode on silicon) formed using a semiconductor process based on silicon wafers.

### SUMMARY

One or more embodiments provide a display device having improved reliability.

One or more embodiments provide an electronic device including the display device.

According to an aspect of an embodiment, a display device includes: a substrate including a first pixel circuit area and a second pixel circuit area, wherein the second pixel circuit area is adjacent to the first pixel circuit area in a first direction; a first driving transistor of a first pixel driving circuit part, wherein the first driving transistor is provided in both of the first and second pixel circuit areas; a second driving transistor of a second pixel driving circuit part, wherein the second driving transistor provided in both of the first and second pixel circuit areas, and is adjacent to the first driving transistor in a second direction intersecting the first direction; a first light-emitting element connected to the first pixel driving circuit part and provided in a first light-emitting area; and a second light-emitting element connected to the second pixel driving circuit part and provided in a second light-emitting area configured to emit light of a different color from the first light-emitting area.

At least one of the first and second driving transistors may include: an active portion including a source region, a drain region, and a channel region between the source region and the drain region of the substrate; and a gate electrode overlapping the channel region of the active portion in a plan view. The active portion and the gate electrode of the at least one of the first and second driving transistors may be provided in both of the first and second pixel circuit areas.

The display device may further include: a first data writing transistor of the first pixel driving circuit part, the first data writing transistor may be provided in the first pixel circuit area, may be connected to the first driving transistor, and may receive a first data voltage in response to a first gate signal; a first emission control transistor of the first pixel driving circuit part, the first emission control transistor may be provided in the first pixel circuit area, may be connected to the first driving transistor, and may receive a driving voltage in response to an emission control signal; and a first initialization transistor of the first pixel driving circuit part, wherein the first initialization transistor may be provided in the first pixel circuit area, may be connected to the first driving transistor, and may receive a first initialization voltage in response to a second gate signal. The first data writing transistor, the first emission control transistor, the first driving transistor, and the first initialization transistor may be sequentially provided along the second direction.

The display device may further include: a second data writing transistor of the second pixel driving circuit part, wherein the second data writing transistor may be provided in the second pixel circuit area, may be connected to the second driving transistor, and may receive a second data voltage in response to the first gate signal; a second emission control transistor of the first pixel driving circuit part, wherein the second emission control transistor may be provided in the first pixel circuit area, may be connected to the second driving transistor, and may receive the driving voltage in response to the emission control signal; and a second initialization transistor of the second pixel driving circuit part, wherein the second initialization transistor may be provided in the second pixel circuit area, may be connected to the second driving transistor, and may receive a second initialization voltage in response to the second gate signal. The second data writing transistor, the second emission control transistor, the second driving transistor, and the second initialization transistor may be sequentially provided along the second direction.

The substrate may further include a third pixel circuit area adjacent to the second pixel circuit area in the first direction, and a fourth pixel circuit area adjacent to the third pixel circuit area in the first direction. The display device may further include: a third driving transistor of a third pixel driving circuit part, wherein the third driving transistor may be provided in both of the third and fourth pixel circuit areas; a fourth driving transistor of a fourth pixel driving circuit part, wherein the fourth driving transistor may be provided in both of the third and fourth pixel circuit areas, and may be adjacent to the third driving transistor in the second direction; a third light-emitting element connected to the third pixel driving circuit part and overlapping a third light-emitting area; and a fourth light-emitting element connected to the fourth pixel driving circuit part and overlapping a fourth light-emitting area configured to emit light of a different color from the third light-emitting area.

The third and fourth driving transistors may be offset, respectively, from the first and second pixel circuit areas along the first and second directions.

The third driving transistor and the first driving transistor may be positioned in a N-th row (where N is natural number) parallel to the first direction, and the fourth driving transistor and the second driving transistor may be positioned in a (N+1)-th row parallel to the first direction and adjacent to the N-th row in the second direction.

The fourth driving transistor and the first driving transistor may be positioned in a N-th row (where N is natural number) parallel to the first direction, and the third driving transistor and the second driving transistor may be positioned in a (N+1)-th row parallel to the first direction and adjacent to the N-th row in the second direction.

The substrate may further include a third pixel circuit area adjacent to the second pixel circuit area in the first direction. The display device may further include: a third driving transistor of a third pixel driving circuit part, wherein the third driving transistor may be provided in each of the first, second, and third pixel circuit areas, and may be adjacent to the second driving transistor in the second direction; and a third light-emitting element connected to the third pixel driving circuit part and overlapping a third light-emitting area configured to emit light of a different color from the first and second light-emitting areas. At least one of the first driving transistor and the second driving transistor may extend from the first and second pixel circuit areas to the third pixel circuit area.

The first driving transistor may include: a first-first driving transistor provided in the first pixel circuit area; and a first-second driving transistor provided in both of the first and second pixel circuit areas, wherein the first-second driving transistor may be connected to the first-first driving transistor, and may be adjacent to the first-first driving transistor in the second direction. The second driving transistor may include: a second-first driving transistor provided in the second pixel circuit area; and a second-second driving transistor provided both of in the first and second pixel circuit areas, wherein the second-second driving transistor may be connected to the second-first driving transistor, and may be adjacent to the second-first driving transistor in a direction opposite to the second direction.

The first-first driving transistor may include a first-first active portion of the substrate provided in the first pixel circuit area and a first-first gate electrode overlapping a channel region of the first-first active portion. The first-second driving transistor may include a first-second active portion of the substrate provided in both of the first and second pixel circuit areas and a first-second gate electrode overlapping a channel region of the first-second active portion. The second-first driving transistor may include a second-first active portion of the substrate provided in the second pixel circuit area and a second-first gate electrode overlapping a channel region of the second-first active portion. The second-second driving transistor may include a second-second active portion of the substrate provided in both of the first and second pixel circuit areas and a second-second gate electrode overlapping a channel region of the second-second active portion.

The display device may further include: a first connection pattern connecting a drain region of the first-first active portion and a source region of the first-second active portion; and a second connection pattern connecting a drain region of the second-first active portion and a source region of the second-second active portion.

The first-first gate electrode and the first-second gate electrode may be configured as a single body, and the second-first gate electrode and the second-second gate electrode may be configured as a single body.

The display device may further include: a first gate connection pattern connecting the first-first gate electrode and the first-second gate electrode; and a second gate connection pattern connecting the second-first gate electrode and the second-second gate electrode.

The display device may further include: a first data writing transistor of the first pixel driving circuit part, wherein the first data writing transistor may be provided in the first pixel circuit area, may be connected to the first driving transistor, and may receive a first data voltage in response to a gate signal; and a first emission control transistor of the first pixel driving circuit part, wherein the first emission control transistor may be provided in the first pixel circuit area, may be connected to the first driving transistor, and may receive a driving voltage in response to an emission control signal. The first data writing transistor, the first driving transistor, and the first emission control transistor may be sequentially provided along the second direction.

The display device may further include: a second data writing transistor of the second pixel driving circuit part, wherein the second data writing transistor may be provided in the second pixel circuit area, may be connected to the second driving transistor, and may receive a second data voltage in response to the gate signal; and a second emission control transistor of the second pixel driving circuit part, wherein the second emission control transistor may be provided in the second pixel circuit area, may be connected to the second driving transistor, and may receive the driving voltage in response to the emission control signal. The second data writing transistor, the second driving transistor, and the second emission control transistor may be sequentially provided along the second direction.

The substrate may include a silicon wafer substrate.

The first and second driving transistors may be p-type metal-oxide-semiconductor (PMOS) transistors.

According to another aspect of an embodiment, an electronic device includes: a display panel including: a substrate including a first pixel circuit area and a second pixel circuit area, wherein the second pixel circuit area is and adjacent to the first pixel circuit area in a first direction; a first driving transistor of a first pixel driving circuit part, wherein the first driving transistor is provided in both of the first and second pixel circuit areas; a second driving transistor of a second pixel driving circuit part, wherein the second driving transistor is provided in both of the first and second pixel circuit areas, and is adjacent to the first driving transistor in a second direction intersecting the first direction; a first light-emitting element connected to the first pixel driving circuit part and provided in a first light-emitting area; and a second light-emitting element connected to the second pixel driving circuit part and provided in a second light-emitting area configured to emit light of a different color from the first light-emitting area; a controller configured to control an operation of the display panel based on an input image data and a control signal; and a processor configured to provide the input image data and the control signal to the controller.

At least one of the first and second driving transistors may include: an active portion including a source region, a drain region, and a channel region between the source region and the drain region of the substrate; and a gate electrode overlapping the channel region of the active portion in a plan view. The active portion and the gate electrode of the at least one of the first and second driving transistors may be provided in both of the first and second pixel circuit areas.

In the display device according to embodiments, each of two driving transistors of two pixel driving circuit parts respectively disposed in a first second pixel circuit area and a second pixel circuit area adjacent to each other may be disposed in both the first pixel circuit area and the second pixel circuit area. In the display device according to embodiments, each of three driving transistors of three pixel driving circuit parts respectively disposed in a first pixel circuit area, a second pixel circuit area, and a third pixel circuit area adjacent to each other may be disposed in all of the first, second, and third pixel circuit areas. Each of the driving transistors may have a sufficiently long channel length. Accordingly, the driving transistors may have a structure robust to variation. Accordingly, the display device may implement high resolution and display quality may be improved.

### BRIEF DESCRIPTION OF DRAWINGS

The above and other aspects will be more apparent from the following description of embodiments, taken in conjunction with the accompanying drawings.

FIG. 1 is a block diagram schematically illustrating a display device according to embodiments.

FIG. 2 is a cross-sectional view schematically illustrating a display panel and an encapsulation substrate of FIG. 1.

FIG. 3 is a circuit diagram illustrating an example of a circuit structure of one pixel of FIG. 1.

FIG. 4 is a cross-sectional view illustrating a transistor included in a pixel driving circuit of FIG. 2.

FIG. 5 is a plan view illustrating a transistor array of FIG. 2.

FIG. 6 is a layout view illustrating an example of a first pixel driving circuit part and a second pixel driving circuit part included in the transistor array of FIG. 5.

FIG. 7 is a plan view for explaining an example of a connection relationship between a driving transistor and a data writing transistor.

FIG. 8 is a layout view illustrating an example of first, second, third, fourth, fifth, and sixth pixel driving circuit parts included in the transistor array of FIG. 5.

FIG. 9 is a layout view illustrating an example of first, second, third, fourth, fifth, and sixth pixel driving circuit parts included in the transistor array of FIG. 5.

FIG. 10 is a layout view illustrating an example of first, second, and third pixel driving circuit parts included in the transistor array of FIG. 5.

FIG. 11 is a circuit view illustrating another example of the circuit structure of one pixel of FIG. 1.

FIG. 12 is a layout view illustrating another example of a first pixel driving circuit part and a second pixel driving circuit part included in the transistor array of FIG. 5.

FIG. 13 is a layout view illustrating another example of a first pixel driving circuit part and a second pixel driving circuit part included in the transistor array of FIG. 5.

FIG. 14 is a layout view illustrating another example of a first pixel driving circuit part and a second pixel driving circuit part included in the transistor array of FIG. 5.

FIG. 15 is a layout view illustrating another example of the first, second, and third pixel driving circuit parts included in the transistor array of FIG. 5.

FIG. 16 is a block diagram illustrating an electronic device according to embodiments.

FIG. 17 is a schematic diagram illustrating an electronic device according to various embodiments.

### DETAILED DESCRIPTION

Hereinafter, embodiments will be explained in detail with reference to the accompanying drawings. The same reference numerals are used for the same components in the drawings, and redundant descriptions of the same components will be omitted.

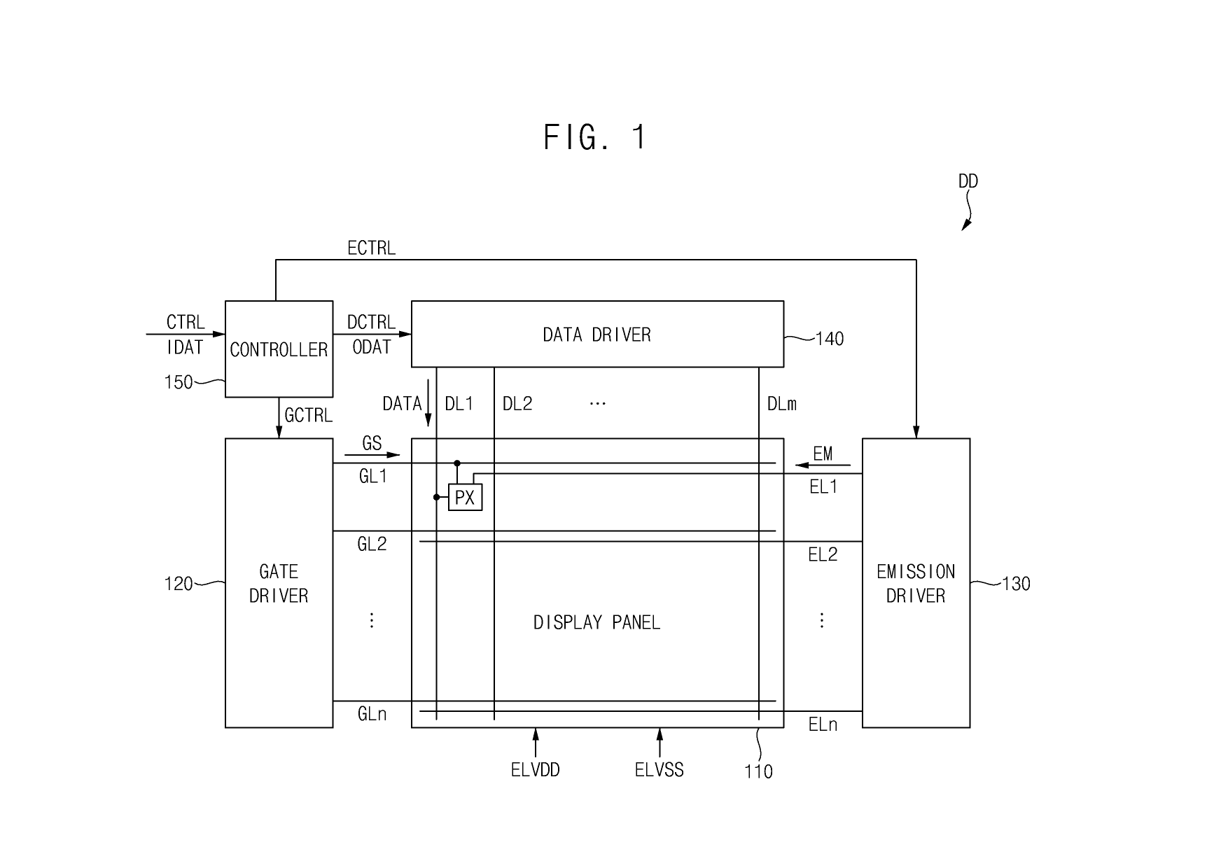

FIG. 1 is a block diagram schematically illustrating a display device according to embodiments. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

Referring to FIG. 1, a display device DD according to embodiments may include a display panel 110, a gate driver (e.g., gate driver circuitry) 120, an emission driver (e.g., emission driver circuitry) 130, a data driver (e.g., data driver circuitry) 140, and a controller (e.g., controller circuitry) 150.

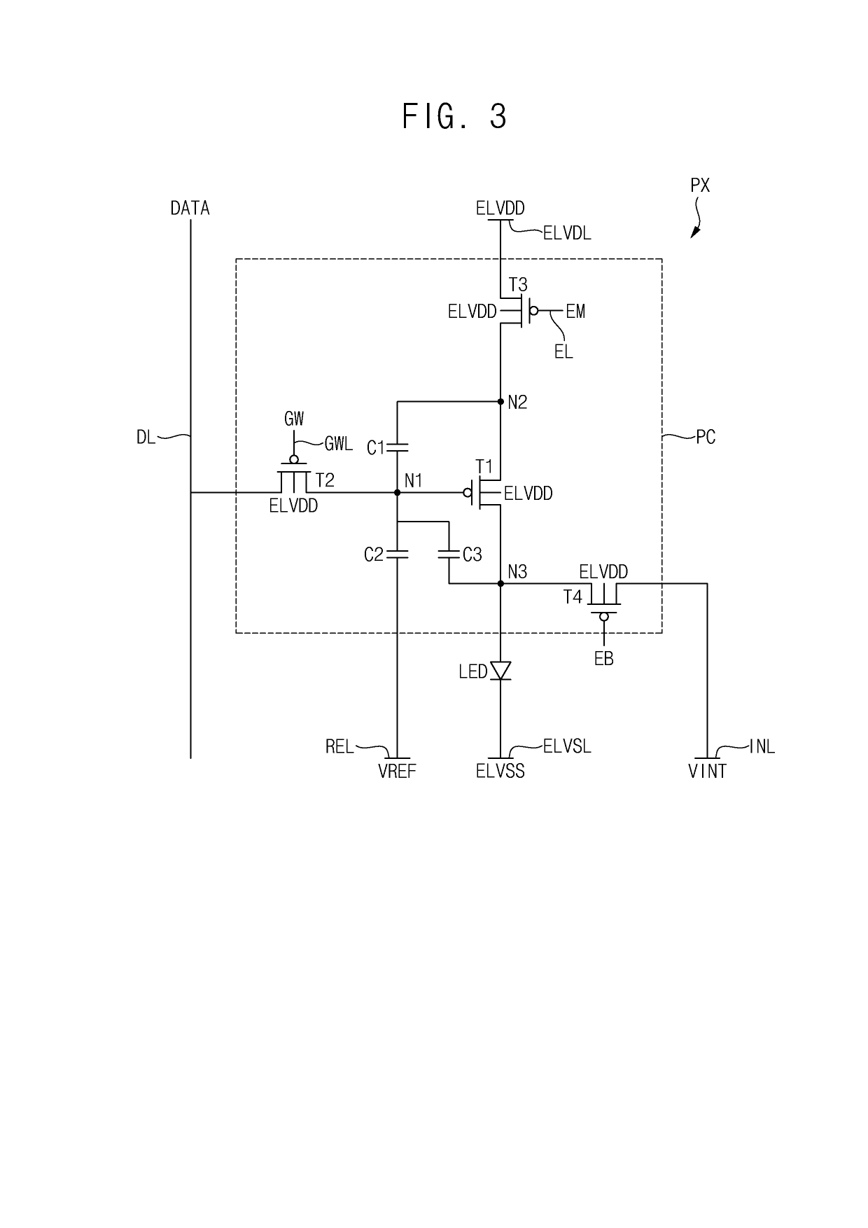

The display panel 110 may include a plurality of gate signal lines GL1 to GLn, a plurality of data lines DL1 to DLm, a plurality of emission control lines EL1 to ELn, and a plurality of pixels PX (where n and m are integers of 2 or more). The gate signal lines GL1 to GLn, the emission control lines EL1 to ELn, and the data lines DL1 to DLm may be electrically connected to the pixels PX. The gate signal lines GL1 to GLn may receive gate signals GS, the emission control lines EL1 to ELn may receive emission control signals EM, and the data lines DL1 to DLm may receive data voltages DATA. For example, the gate signals GS may include gate signals GW and EB in FIG. 3 or a gate signal GW in FIG. 11.

Each of the gate signal lines GL1 to GLn and each of the emission control lines EL1 to ELn may extend in a first direction (e.g., row direction). Each of the data lines DL1 to DLm may extend in a second direction (e.g., column direction) intersecting the first direction. The gate signal lines GL1 to GLn, the emission control lines EL1 to ELn, and the data lines DL1 to DLm may be insulated from each other. The pixels PX may be arranged in areas where the gate signal lines GL1 to GLn (or the emission control lines EL1 to ELn) and the data lines DL1 to DLm intersect.

In an embodiment, each of the pixels PX may include a switching transistor (e.g., T2 in FIG. 3) which provides the data voltage DATA in response to the gate signal GS, a storage capacitor which stores the data voltage DATA provided by the switching transistor, a driving transistor which generates a driving current based on the stored data voltage DATA, and a light-emitting element which emits light based on the driving current generated by the driving transistor. For example, the light-emitting element may include a light emitting diode (LED), an organic light emitting diode (OLED), or a quantum dot (QD) light-emitting element.

The pixels PX may receive a driving voltage ELVDD and a common voltage ELVSS. The pixels PX may receive the data voltage DATA in response to the gate signal GS and the emission control signal EM, and may generate light of a gray level corresponding to the data voltage DATA using the driving voltage ELVDD and the common voltage ELVSS.

The gate driver 120 may provide the gate signals GS to the pixels PX through the gate signal lines GL1 to GLn based on a gate control signal GCTRL received from the controller 150. In an embodiment, the gate driver 120 may sequentially provide the gate signals GS to the pixels PX in units of rows. The gate control signal GCTRL may include a gate start signal, a gate clock signal, and the like, however embodiments are not necessarily limited thereto. For example, the gate driver 120 may be integrated or formed in a peripheral portion of the display panel 110. Alternatively, the gate driver 120 may be implemented using one or more integrated circuits (ICs).

The emission driver 130 may provide the emission control signals EM to the pixels PX through the emission control lines EL1 to ELn based on an emission control signal ECTRL received from the controller 150. In an embodiment, the emission driver 130 may sequentially provide the emission control signals EM to the pixels PX in units of rows. The emission control signal ECTRL may include an emission start signal, an emission clock signal, and the like, however embodiments are not necessarily limited thereto. For example, the emission driver 130 may be integrated or formed in a peripheral portion of the display panel 110. Alternatively, the emission driver 130 may be implemented using one or more integrated circuits (ICs).

The data driver 140 may receive a data control signal DCTRL and an output image data ODAT from the controller 150 and may provide the data voltages DATA to the pixels PX through the data lines DL1 to DLm based on the data control signal DCTRL and the output image data ODAT. The data control signal DCTRL may include an output data enable signal, a horizontal start signal, a load signal, and the like, however embodiments are not necessarily limited thereto. For example, the data driver 140 may be implemented as a single integrated circuit, and the integrated circuit may be referred to as a timing controller embedded data driver (TED). Alternatively, the data driver 140 may be implemented using separate integrated circuits.

The controller 150 may receive an input image data IDAT and a control signal CTRL from an external processor. For example, the controller 150 may be a timing controller, and the processor may be an application processor (AP), a graphic processing unit (GPU), or a graphic card. In an embodiment, the input image data IDAT may be RGB image data including red, green, and blue image data. The control signal CTRL may include a vertical sync signal, a horizontal sync signal, an input data enable signal, a master clock signal, and the like, however embodiments are not necessarily limited thereto.

The controller 150 may generate the gate control signal GCTRL, the emission control signal ECTRL, the data control signal DCTRL, and the output image data ODAT based on the input image data IDAT and the control signal CTRL. The controller 150 may control the operation of the gate driver 120 by providing the gate control signal GCTRL, control the operation of the emission driver 130 by providing the emission control signal ECTRL, and control the operation of the data driver 140 by providing the output image data ODAT and the data control signal DCTRL. That is, the controller 150 may control the driving of the display panel 110.

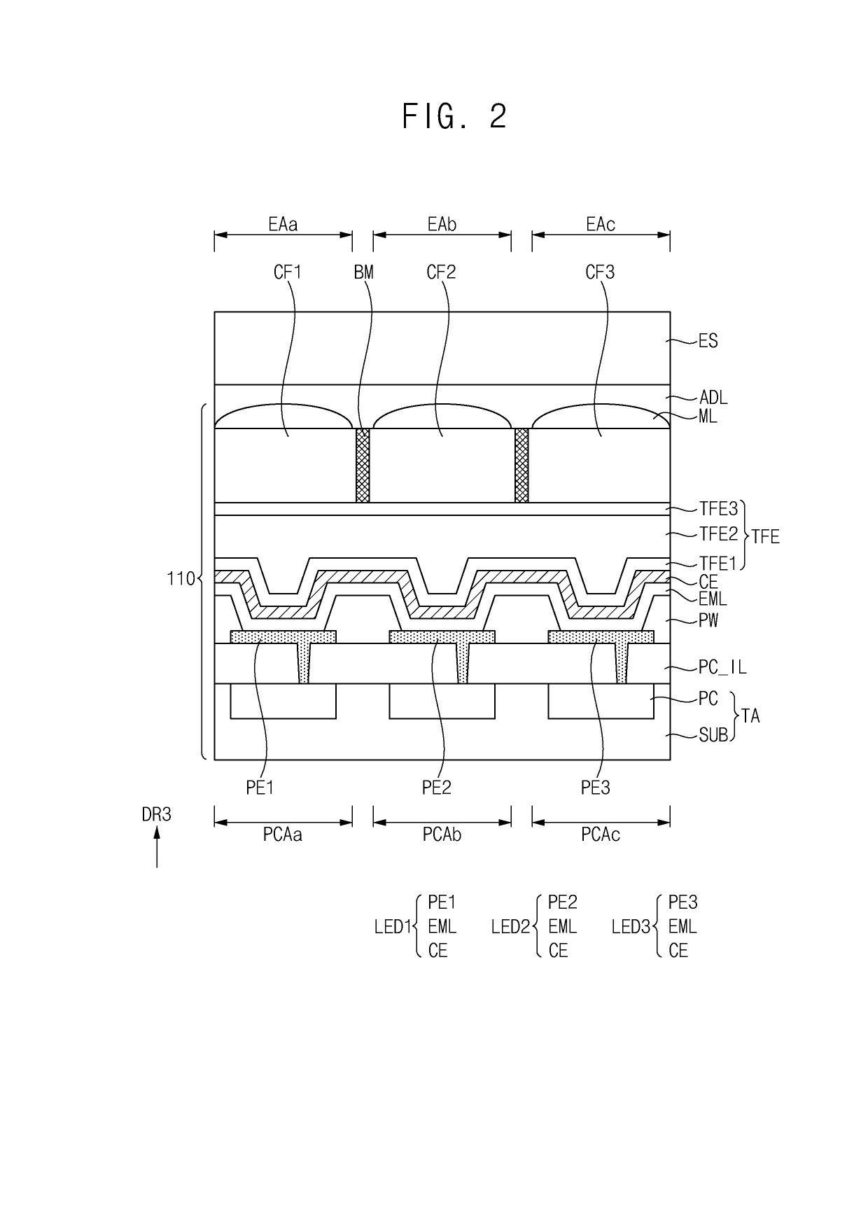

FIG. 2 is a cross-sectional view schematically illustrating a display panel and an encapsulation substrate of FIG. 1.

Referring to FIGS. 1 and 2, the display device DD according to embodiments may further include an encapsulation substrate ES disposed on the display panel DP. The display panel DP may include a transistor array TA, a circuit insulating layer PC_IL, first, second, and third light-emitting elements LED1, LED2, and LED3, a partition wall PW, an encapsulation layer TFE, first, second, and third color filter layers CF1, CF2, and CF3, a light blocking layer BM, and a lens layer.

Here, the transistor array TA may include a substrate SUB and a plurality of pixel driving circuit parts (i.e., pixel driving circuits) PC. The first light-emitting element LED1 may include a first pixel electrode PE1, a light-emitting layer EML, and a common electrode CE, the second light-emitting element LED2 may include a second pixel electrode PE2, the light-emitting layer EML, and the common electrode CE, and the third light-emitting element LED3 may include a third pixel electrode PE3, the light-emitting layer EML, and the common electrode CE.

The substrate SUB may include a first pixel circuit area PCAa, a second pixel circuit area PCAb, and a third pixel circuit area PCAc.

In an embodiment, the substrate SUB may include a silicon wafer substrate formed using a semiconductor process. The substrate SUB may serve as a support member for supporting other components of the display device DD. For example, the substrate SUB may include a semiconductor material (e.g., a group IV semiconductor, a group III-V compound semiconductor, a group II-VI semiconductor, and the like). However, embodiments are not necessarily limited thereto.

The pixel driving circuit parts PC may be disposed in the substrate SUB. Each of the pixel driving circuit parts PC may overlap the first, second, and third pixel circuit areas PCAa, PCAb, and PCAc, respectively. For example, the overlap may be along a third direction DR3 , (e.g., vertical direction) intersecting the first direction DR1 and the second direction DR2. Each of the pixel driving circuit parts PC may include various driving elements for driving the first, second, and third light-emitting elements LED1, LED2, and LED3. For example, each of the pixel driving circuit parts PC may include at least one transistor formed by a semiconductor process and at least one capacitor formed by a semiconductor process. Each of the pixel driving circuit parts PC may correspond to the pixel driving circuit part PC shown in FIG. 3. That is, each of the pixel driving circuit parts PC may include four transistors and three (or two) capacitors.

The circuit insulating layer PC_IL may be disposed on the pixel driving circuit portions PC. The circuit insulating layer PC_IL may prevent contact between the first, second, and third pixel electrodes PE1, PE2, and PE3 and the pixel driving circuit parts PC. The circuit insulating layer PC_IL may include an organic material and/or an inorganic material. For example, the circuit insulating layer PC_IL may include multiple layers formed of various insulating materials.

The first, second, and third pixel electrodes PE1, PE2, and PE3 may be disposed on the circuit insulating layer PC_IL. The first pixel electrode PE1 may be disposed in a first light-emitting area EAa which emits light of a first color, the second pixel electrode PE2 may be disposed in a second light-emitting area EAb which emits light of a second color, and the third pixel electrode PE3 may be disposed in a third light-emitting area EAc which emits light of a third color. For example, the first color may be red, the second color may be green, and the third color may be blue. However, embodiments are not necessarily limited thereto.

For example, along the third direction DR3, the first light-emitting area EAa may at least partially overlap the first pixel circuit area PCAa, the second light-emitting area EAb may at least partially overlap the second pixel circuit area PCAb, and the third light-emitting area EAc may at least partially overlap the third pixel circuit area PCAc.

The first pixel electrode PE1 may be electrically connected to the pixel driving circuit part PC disposed in the first pixel circuit area PCAa through a contact hole penetrating the circuit insulating layer PC_IL, the second pixel electrode PE2 may be electrically connected to the pixel driving circuit part PC disposed in the second pixel circuit area PCAb through a contact hole, and the third pixel electrode PE3 may be electrically connected to the pixel driving circuit part PC disposed in the third pixel circuit area PCAc through a contact hole.

In FIG. 3, for convenience of explanation, the first, second, and third pixel electrodes PE1, PE2, and PE3 are illustrated as being directly connected to the pixel driving circuit part PC, however each of the first, second, and third pixel electrodes PE1, PE2, and PE3 may be electrically connected to the pixel driving circuit part PC through at least one conductive pattern.

The first, second, and third pixel electrodes PE1, PE2, and PE3 may include a metal, an alloy, a metal nitride, a conductive metal oxide, a transparent conductive material, and the like. The first, second, and third pixel electrodes PE1, PE2, and PE3 may include the same material and may be formed through the same process. For example, each of the first, second, and third pixel electrodes PE1, PE2, and PE3 may have a multilayer structure including ITO/Ag/ITO. However, embodiments are not necessarily limited thereto. Each of the first, second, and third pixel electrodes PE1, PE2, and PE3 may be an anode electrode. Each of first, second, and third pixel electrodes PE1, PE2, and PE3 may be a reflective electrode. However, embodiments are not necessarily limited thereto.

The partition wall PW may be disposed on the circuit insulating layer PC_IL. The partition wall PW may cover the edges of each of the first, second, and third pixel electrodes PE1, PE2, and PE3. The partition wall PW may also expose at least a portion of the upper surface of each of the first, second, and third pixel electrodes PE1, PE2, and PE3. For example, the partition wall PW may include an inorganic material such as silicon oxide, silicon nitride, silicon oxynitride, and the like. These may be used alone or in combination with each other. Alternatively, the partition wall PW may include an organic material. In an embodiment, the partition wall PW may have a multilayer structure, however embodiments are not necessarily limited thereto.

The light-emitting layer EML may be disposed on the first, second, and third pixel electrodes PE1, PE2, and PE3 and the partition wall PW. The light-emitting layer EML may be a common layer commonly formed over the first, second, and third light-emitting areas EAa, EAb, and EAc. That is, the light-emitting layer EML may extend continuously over an entirety of the first, second, and third light-emitting areas EAa, EAb, and EAc. For example, the light-emitting layer EML may include a hole injection layer, a hole transport layer, an organic light-emitting layer, an electron injection layer, and an electron transport layer. In an embodiment, the organic light-emitting layer may include a light-emitting material which emits white light. For example, the white light may be a mixture of blue, green, and red light. Alternatively, the white light may be a mixture of blue and yellow light.

However, embodiments are not necessarily limited thereto. The light-emitting layer EML may include a first light-emitting layer overlapping (i.e., along the third direction DR3) the first light-emitting area EAa and including a material which emits light of a first color (e.g., red light), a second light-emitting layer overlapping (i.e., along the third direction DR3) the second light-emitting area EAb and including a material which emits light of a second color (e.g., green light), and a third light-emitting layer overlapping (i.e., along the third direction DR3) the third light-emitting area EAc and including a material which emits light of a third color (e.g., blue light). In this case, the first, second, and third light-emitting layers may be separated from each other, and the first, second, and third color filter layers CF1, CF2, and CF3 and the light blocking layer BM may be omitted.

The common electrode CE may be disposed on the light-emitting layer EML. The common electrode CE may be a common layer commonly formed over the first, second, and third emission areas EAa, EAb, and EAc. That is, the common electrode CE may continuously extend over the entirety of the first, second, and third light-emitting areas EAa, EAb, and EAc. For example, the common electrode CE may include a metal, an alloy, a metal nitride, a conductive metal oxide, a transparent conductive material, and the like. These may be used alone or in combination with each other. The common electrode CE may be a cathode electrode. The common electrode CE may be a transmissive or semi-transmissive electrode.

Accordingly, the first pixel electrode PE1, the light-emitting layer EML, and the common electrode CE may form the first light-emitting element LED1, the second pixel electrode PE2, the light-emitting layer EML, and the common electrode CE may form the second light-emitting device LED2, and the third pixel electrode PE3, the light-emitting layer EML, and the common electrode CE may form the third light-emitting device LED3. The first, second, and third light-emitting elements LED1, LED2, and LED3 may be electrically connected to the pixel driving circuit parts PC of the first, second, and third pixel circuit areas PCAa, PCAb, and PCAc, respectively.

The encapsulation layer TFE may be disposed on the common electrode CE. The encapsulation layer TFE may continuously extend over the entirety of the first, second, and third pixel circuit areas PCAa, PCAb, and PCAc. The encapsulation layer TFE may prevent impurities, moisture, and the like from penetrating into the first, second, and third light-emitting elements LED1, LED2, and LED3 from the outside.

The encapsulation layer TFE may include at least one inorganic layer and at least one organic layer. For example, the encapsulation layer TFE may include a first inorganic encapsulation layer TFE1, an organic encapsulation layer TFE2 disposed on the first inorganic encapsulation layer TFE1, and a second inorganic encapsulation layer TFE3 disposed on the organic encapsulation layer TFE2. The organic encapsulation layer TFE2 may have a substantially flat upper surface.

For example, the first and third inorganic encapsulation layers TFE1 and TFE3 may include silicon oxide, silicon nitride, silicon oxynitride, and the like. These may be used alone or in combination with each other. The organic encapsulation layer TFE2 may include a polymeric cured material such as polyacrylate.

The first, second, and third color filter layers CF1, CF2, and CF3 may be disposed on the encapsulation layer TFE. Along the third direction DR3, the first color filter layer CF1 may overlap the first light-emitting area EAa, the second color filter layer CF2 may overlap the second light-emitting area EAb, and the third color filter layer CF3 may overlap the third light-emitting area EAc.

Each of the first, second, and third color filter layers CF1, CF2, and CF3 may selectively transmit light of a specific wavelength and absorb light of the remaining wavelengths. For example, red light may be transmitted through the first color filter layer CF1, green light may be transmitted through the second color filter layer CF2, and blue light may be transmitted through the third color filter layer CF3. Accordingly, the first light-emitting area EAa may emit red light, the second light-emitting area EAb may emit green light, and the third light-emitting area EAc may emit blue light.

The light blocking layer BM may be disposed on the encapsulation layer TFE. The light blocking layer BM may be disposed between the first, second, and third color filter layers CF1, CF2, and CF3. That is, the light blocking layer BM may not overlap the first, second, and third light-emitting areas EAa, EAb, and EAc along the third direction DR3. The light blocking layer BM may block light incident on the light blocking layer BM. Accordingly, the light blocking layer BM may prevent color mixing between the first, second, and third light-emitting areas EAa, EAb, and EAc. For example, the light blocking layer BM may include an organic material and/or an inorganic material containing black pigment, black dye, and the like.

The lens layer may be disposed on the first, second, and third color filter layers CF1, CF2, and CF3 and the light blocking layer BM. The lens layer may include a plurality of micro lenses ML. The micro lenses ML may improve light extraction efficiency. Each of the micro lenses ML may overlap the first, second, and third color filter layers CF1, CF2, and CF3 along the third direction DR3. The micro lenses ML may have a predetermined refractive index for visible light. For example, the micro lenses ML may have a refractive index of about 1.5 to about 1.7 for visible light. However, embodiments are not necessarily limited thereto. For example, each of the micro lenses ML may have a convex cross-sectional shape.

The encapsulation substrate ES may be disposed on the lens layer. The encapsulation substrate ES may be attached to the display panel 110 through an adhesive layer ADL. The encapsulation substrate ES may protect the display panel 110 from moisture permeation or gas intrusion. The encapsulation substrate ES may include a transparent insulating substrate. For example, the encapsulation substrate ES may include glass. For example, the adhesive layer ADL may include an optical clear adhesive (OCA), a pressure sensitive adhesive (PSA), a photo-curable resin, a thermosetting resin, or the like.

FIG. 3 is a circuit diagram illustrating an example of a circuit structure of one pixel of FIG. 1.

Referring to FIG. 3, each pixel PX may include a pixel driving circuit part PC and a light-emitting element LED electrically connected to the pixel driving circuit part PC. The pixel driving circuit PC may generate a driving current, and the light-emitting element LED may generate light based on the driving current.

In an embodiment, the pixel driving circuit part PC may include a first transistor T1, a second transistor T2, a third transistor T3, a fourth transistor T4, a first capacitor C1, a second capacitor C2, and a third capacitor C3.

In an embodiment, the first, second, third, and fourth transistors T1, T2, T3, and T4 may all be MOSFET (metal-oxide-semiconductor field-effect transistor) formed through a semiconductor process.

In an embodiment, the first, second, third, and fourth transistors T1, T2, T3, and T4 may all be p-type metal-oxide-semiconductor field-effect (PMOSFET or PMOS) transistors. However, embodiments are not necessarily limited thereto, and some of the first, second, third, and fourth transistors T1, T2, T3, and T4 may be PMOS transistors and the rest may be n-type metal-oxide-semiconductor field-effect (NMOSFET or NMOS) transistors.

The first transistor T1 may include a gate electrode, a source electrode, and a drain electrode. The gate electrode of the first transistor T1 may be connected to a first node N1. The source electrode of the first transistor T1 may be connected to a second node N2. The drain electrode of the first transistor T1 may be connected to a third node N3. The first transistor T1 may provide the driving current to the light-emitting element LED. The first transistor T1 may be referred to as a driving transistor.

The first transistor T1 may further include a body electrode. The body electrode of the first transistor T1 may receive the driving voltage ELVDD. For example, a driving voltage line ELVDL which receives the driving voltage ELVDD may be connected to the body electrode of the first transistor T1. Alternatively, a separate power supply other than the driving voltage ELVDD may be applied to the body electrode of the first transistor T1.

The second transistor T2 may include a gate electrode, a source electrode, and a drain electrode. A first gate signal line GWL which receives a first gate signal GW may be connected to the gate electrode of the second transistor T2. The data line DL which receives the data voltage DATA may be connected to the source electrode of the second transistor T2. The drain electrode of the second transistor T2 may be connected to the first node N1. That is, the second transistor T2 may be electrically connected to the first transistor T1. The second transistor T2 may be referred to as a data writing transistor.

The second transistor T2 may further include a body electrode. The body electrode of the second transistor T2 may receive the driving voltage ELVDD. For example, the driving voltage line ELVDL which receives the driving voltage ELVDD may be connected to the body electrode of the second transistor T2. Alternatively, a separate power supply other than the driving voltage ELVDD may be applied to the body electrode of the second transistor T2.

The second transistor T2 may be turned on or off in response to the first gate signal GW. For example, in case that the first gate signal GW has an activation level, the second transistor T2 may be turned on. In this case, the second transistor T2 may provide the data voltage DATA to the first node N1. Conversely, in case that the first gate signal GW has an inactivation level, the second transistor T2 may be turned off. In this case, the second transistor T2 may block the supply of the data voltage DATA.

The third transistor T3 may include a gate electrode, a source electrode, and a drain electrode. The gate electrode of the third transistor T3 may be connected to an emission control line EL which receives the emission control signal EM. The source electrode of the third transistor T3 may be connected to a driving voltage line ELVDL which receives the driving voltage ELVDD. The drain electrode of the third transistor T3 may be connected to the second node N2. That is, the third transistor T3 may be electrically connected to the first transistor T1. The third transistor T3 may be referred to as an emission control transistor.

The third transistor T3 may further include a body electrode. The body electrode of the third transistor T3 may receive the driving voltage ELVDD. For example, the driving voltage line ELVDL which receives the driving voltage ELVDD may be connected to the body electrode of the third transistor T3. Alternatively, a separate power supply other than the driving voltage ELVDD may be applied to the body electrode of the third transistor T3.

The third transistor T3 may be turned on or off in response to the emission control signal EM. For example, in case that the emission control signal EM has an activation level, the third transistor T3 may be turned on. In this case, the third transistor T3 may provide the driving current generated by the first transistor T1 to an anode electrode of the light-emitting element LED. Conversely, in case that the emission control signal EM has an inactivation level, the third transistor T3 may be turned off. In this case, the third transistor T3 may block the supply of the driving current generated by the first transistor T1.

The fourth transistor T4 may include a gate electrode, a source electrode, and a drain electrode. A second gate signal line EBL which receives a second gate signal EB may be connected to the gate electrode of the fourth transistor T4. An initialization voltage line INL which receives an initialization voltage VINT may be connected to the source electrode of the fourth transistor T4. The drain electrode of the fourth transistor T4 may be connected to the third node N3. That is, the fourth transistor T4 may be electrically connected to the first transistor T1. The fourth transistor T4 may be referred to as an initialization transistor.

The fourth transistor T4 may further include a body electrode. The body electrode of the fourth transistor T4 may receive the driving voltage ELVDD. For example, the driving voltage line ELVDL which receives the driving voltage ELVDD may be connected to the body electrode of the fourth transistor T4. Alternatively, a separate power supply other than the driving voltage ELVDD may be applied to the body electrode of the fourth transistor T4.

The fourth transistor T4 may be turned on or off in response to the second gate signal EB. For example, in case that the second gate signal EB has an activation level, the fourth transistor T4 may be turned on. In this case, the fourth transistor T4 may provide the initialization voltage VINT to the third node N3. Conversely, in case that the second gate signal EB has an inactivation level, the fourth transistor T4 may be turned off. In this case, the fourth transistor T4 may block the supply of the initialization voltage VINT.

The first capacitor C1 may include a first electrode and a second electrode. The first electrode of the first capacitor C1 may be connected to the first node N1, and the second electrode of the first capacitor C1 may be connected to the second node N2.

The second capacitor C2 may include a first electrode and a second electrode. A reference voltage line REL which receives a reference voltage VREF may be connected to the first electrode of the second capacitor C2. The second electrode of the second capacitor C2 may be connected to the first node N1.

The third capacitor C3 may include a first electrode and a second electrode. The first electrode of the third capacitor C3 may be connected between the second capacitor C2 and the first node N1. The second electrode of the third capacitor C3 may be connected to the third node N3. Alternatively, the third capacitor C3 may be omitted.

The light-emitting element LED may include an anode electrode and a cathode electrode. The anode electrode of the light-emitting element LED may be connected to the third node N3. A common voltage line ELVSL which receives the common voltage ELVSS may be connected to the cathode electrode of the light-emitting element LED. The common voltage ELVSS may have a lower voltage level than the driving voltage ELVDD.

Although FIG. 3 illustrates that one pixel driving circuit part PC includes four transistors and three capacitors, embodiments are not necessarily limited thereto.

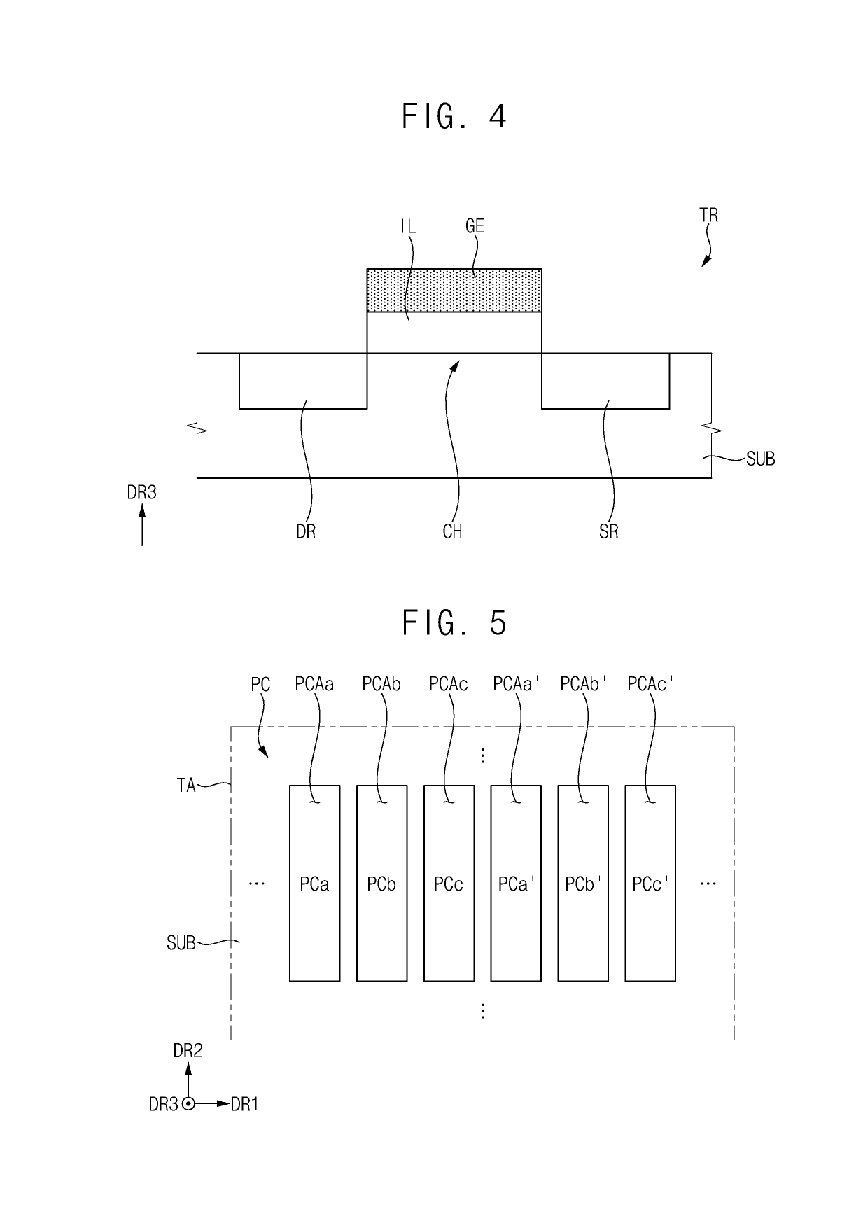

FIG. 4 is a cross-sectional view illustrating a transistor included in a pixel driving circuit of FIG. 2.

Referring to FIGS. 2 and 4, the pixel driving circuit part PC may include at least one transistor TR formed by a semiconductor process. The transistor TR may correspond to any one of the first, second, third, and fourth transistors T1, T2, T3, and T4 in FIG. 3.

The transistor TR may include an active portion, an insulating layer IL, and a gate electrode GE. A portion of the substrate SUB may define the active portion. That is, the substrate SUB may include the active portion. The active portion may include a source region SR, a drain region DR, and a channel region CH.

The substrate SUB may include a semiconductor material. In an embodiment, the substrate SUB may be an n-type semiconductor substrate doped with n-type impurities or a p-type semiconductor substrate doped with p-type impurities.

The source region SR and the drain region DR may be disposed in the active portion. Specifically, the source region SR may be disposed in one side of the interior of the active portion, and the drain region DR may be disposed in the other side of the interior the active portion. For example, the source region SR and the drain region DR may include the same semiconductor material as the substrate SUB. The source region SR and the drain region DR may serve as a source electrode and a drain electrode of the transistor TR, respectively.

Impurities may be doped into the source region SR and the drain region DR. Accordingly, the source region SR and the drain region DR may be conductive regions. The doping concentrations of the source region SR and the drain region DR may be higher than the doping concentration of the substrate SUB. In an embodiment, the source region SR and the drain region DR may be doped with p-type impurities. However, embodiments are not necessarily limited thereto.

At least a portion of the substrate SUB contacting the source region SR and the drain region DR may be doped with impurities of an opposite type to impurities of the source region SR and the drain region DR. For example, a well region doped with impurities of an opposite type to impurities of the source region SR and the drain region DR may be formed in the substrate SUB, and this well region may contact the source region SR and the drain region DR. In this case, the substrate SUB may be a semiconductor substrate doped with the same type of impurities as the source region SR and the drain region DR. Alternatively, the well region may not be formed in the substrate SUB. In this case, the substrate SUB may be a semiconductor substrate doped with impurities of an opposite type to impurities of the source region SR and the drain region DR.

In an embodiment, in case that the source region SR and the drain region DR are doped with p-type impurities, at least a portion of the substrate SUB contacting the source region SR and the drain region DR may be doped with n-type impurities.

The channel region CH may be positioned between the source region SR and the drain region DR in the substrate SUB. For example, the channel region CH may include the same semiconductor material as the substrate SUB. The channel region CH may be a region of the substrate SUB in which carriers having charges conduct in case that a voltage is applied to the gate electrode GE.

The channel region CH may be defined as a current path formed between the source region SR and the drain region DR. For example, in case that the source region SR and the drain region DR are doped with p-type impurities, the channel region CH may be formed in case that a negative voltage is applied to the gate electrode GE and may transmit current through the movement of holes.

The insulating layer IL may be disposed on the substrate SUB. Specifically, the insulating layer IL may overlap the channel region CH. The insulating layer IL may include silicon oxide (e.g., SiO₂), silicon nitride, or a dielectric material having a high dielectric constant (i.e., a high-κ dielectric). A material having the high dielectric constant may refer to a dielectric material having a higher dielectric constant than silicon oxide. For example, the material having a high dielectric constant may include aluminum oxide (Al₂O₃), tantalum oxide (Ta₂O₅), titanium oxide (TiO₂), yttrium oxide (Y₂O₃), zirconium oxide (ZrO₂), zirconium silicon oxide (ZrSiₓO_{y}), hafnium oxide (HfO₂), hafnium silicon oxide (HfSiₓO_{y}), lanthanum oxide (La₂O₃), lanthanum aluminum oxide (LaAlₓO_{y}), lanthanum hafnium oxide (LaHfₓO_{y}), hafnium aluminum oxide (HfAlₓO_{y}), praseodymium oxide (Pr₂O₃), and the like. These may be used alone or in combination with each other. However, embodiments are not necessarily limited thereto.

The gate electrode GE may be disposed on the insulating layer IL. The gate electrode GE may overlap the channel region CH in the plan view (i.e., along the third direction DR3). The gate electrode GE may include a metal or a metal nitride. Examples of the metal may include aluminum, tungsten, copper, molybdenum, and the like. Examples of the metal nitride may include titanium nitride (TiN), tantalum nitride (TaN), tungsten nitride (WN), and the like. These may be used alone or in combination with each other. Alternatively, the gate electrode GE may include a semiconductor material such as doped polysilicon. The gate electrode GE may have a single-layer structure or a multi-layer structure including a plurality of layers.

FIG. 5 is a plan view illustrating a transistor array of FIG. 2.

Referring to FIGS. 2 and 5, as described above, the transistor array TA may include the substrate SUB and the pixel driving circuit parts PC.

The substrate SUB may further include a fourth pixel circuit area PCAa’, a fifth pixel circuit area PCAb’, and a sixth pixel circuit area PCAc’.

The second pixel circuit area PCAb may be adjacent to the first pixel circuit area PCAa in a first direction DR1, and the third pixel circuit area PCAc may be adjacent to the second pixel circuit area PCAb in the first direction DR1. In addition, the fourth pixel circuit area PCAa’ may be adjacent to the third pixel circuit area PCAc in the first direction DR1, the fifth pixel circuit area PCAb’ may be adjacent to the fourth pixel circuit area PCAa’ in the first direction DR1, and the sixth pixel circuit area PCAc’ may be adjacent to the fifth pixel circuit area PCAb’ in the first direction DR1. That is, the first, second, third, fourth, fifth, and sixth pixel circuit areas PCAa, PCAb, PCAc, PCAa’, PCAb’, and PCAc’ may be sequentially arranged along the first direction DR1. For example, each of the first, second, third, fourth, fifth, and sixth pixel circuit areas PCAa, PCAb, PCAc, PCAa’, PCAb’, and PCAc’ may have common dimensions along each of the first direction DR1 and the second direction DR2.

The pixel driving circuit parts PC may include a first pixel driving circuit part PCa, a second pixel driving circuit part PCb, a third pixel driving circuit part PCc, a fourth pixel driving circuit part PCa’, a fifth pixel driving circuit part PCb’, and a sixth pixel driving circuit part PCc’.

The first pixel driving circuit part PCa may be disposed in the first pixel circuit area PCAa and may be electrically connected to the first light-emitting element LED1 disposed in the first light-emitting area EAa. The second pixel driving circuit part PCb may be disposed in the second pixel circuit area PCAb and may be electrically connected to the second light-emitting element LED2 disposed in the second light-emitting area EAb. The third pixel driving circuit part PCc may be disposed in the third pixel circuit area PCAc and may be electrically connected to the third light-emitting element LED3 disposed in the third light-emitting area EAc.

In addition, the fourth pixel driving circuit part PCa’ may be disposed in the fourth pixel circuit area PCAa’ and may be electrically connected to a fourth light-emitting element disposed in a fourth light-emitting area. The fifth pixel driving circuit part PCb’ may be disposed in the fifth pixel circuit area PCAb’ and may be electrically connected to a fifth light-emitting element disposed in a fifth light-emitting area. The sixth pixel driving circuit part PCc’ may be disposed in the sixth pixel circuit area PCAc’ and may be electrically connected to a sixth light-emitting element disposed in a sixth light-emitting area.

The first, second, and third light-emitting areas EAa, EAb, and EAc may emit light of different colors, and the fourth, fifth, and sixth light-emitting areas may emit light of different colors. For example, the first light-emitting area EAa and the fourth light-emitting area may emit light of a first color (e.g., red light), the second light-emitting area EAb and the fifth light-emitting area may emit light of a second color (e.g., green light), and the third light-emitting area EAc and the sixth light-emitting area may emit light of a third color (e.g., blue light). However, embodiments are not necessarily limited thereto.

The first, second, and third light-emitting elements LED1, LED2, and LED3 may emit light of the same color, and the fourth, fifth, and sixth light-emitting elements may emit light of the same color. For example, the first, second, and third light-emitting elements LED1, LED2, and LED3 may emit white light, and the fourth, fifth, and sixth light-emitting elements may emit white light. In this case, color filter layers (e.g., CF1, CF2, and CF3 in FIG. 2) may be disposed on the first, second, and third light-emitting elements LED1, LED2, and LED3 and the fourth, fifth, and sixth light-emitting elements. However, embodiments are not necessarily limited thereto.

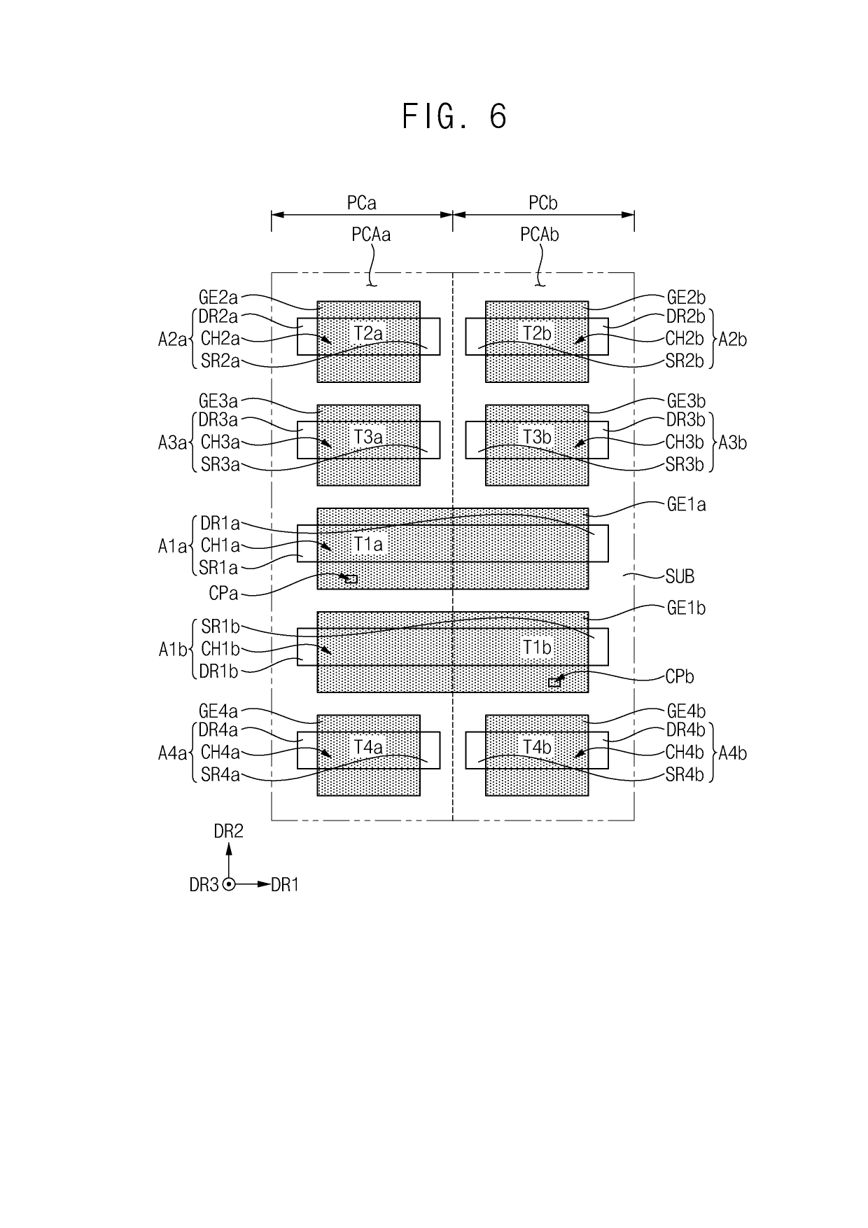

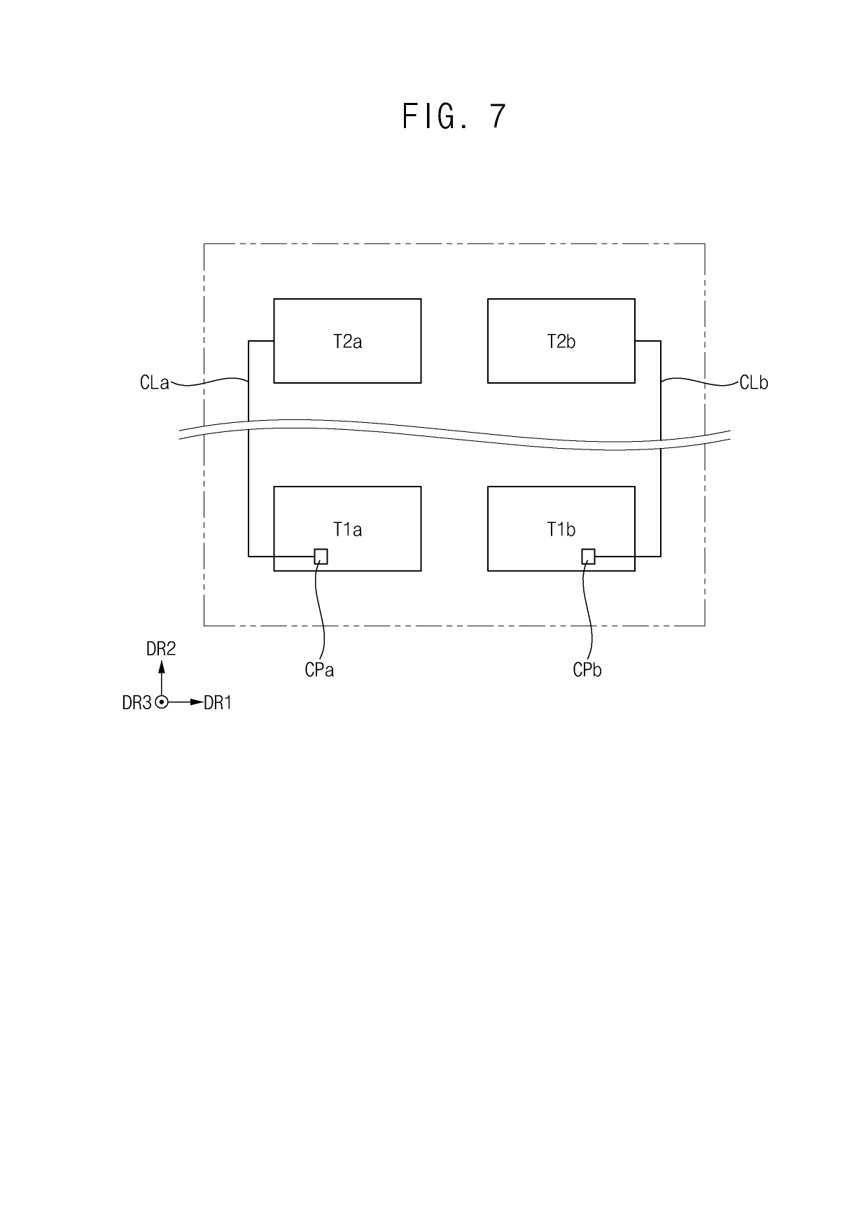

FIG. 6 is a layout view illustrating an example of a first pixel driving circuit part and a second pixel driving circuit part included in the transistor array of FIG. 5. FIG. 7 is a plan view for explaining an example of a connection relationship between a driving transistor and a data writing transistor.

Hereinafter, an example of the arrangement structure of transistors included in the first and second pixel driving circuit parts PCa and PCb of the transistor array TA will be described in more detail. In addition, the description of the first and second pixel driving circuit parts PCa and PCb described below may be substantially equally applied to the third and fourth pixel driving circuit parts PCc and PCa’ and the fifth and sixth pixel driving circuit parts PCb’ and PCc’ in FIG. 5.

Referring to FIGS. 6 and 7, the first pixel driving circuit part PCa may include a first driving transistor T1a, a first data writing transistor T2a, a first emission control transistor T3a, and a first initialization transistor T4a disposed in the first pixel circuit area PCAa. Similarly, the second pixel driving circuit part PCb may include a second driving transistor T1b, a second data writing transistor T2b, a second emission control transistor T3b, and a second initialization transistor T4b disposed in the second pixel circuit area PCAb.

The first driving transistor T1a, the first data writing transistor T2a, the first emission control transistor T3a, and the first initialization transistor T4a may be disposed in a row along the second direction DR2. In an embodiment, the first data writing transistor T2a, the first emission transistor T3a, the first driving transistor T1a, and the first initialization transistor T4a may be sequentially disposed along a direction opposite to the second direction DR2. However, embodiments are not necessarily limited thereto, and the positions of the transistors disposed in the first pixel circuit area PCAa may be interchanged with each other.

The second driving transistor T1b, the second data writing transistor T2b, the second emission control transistor T3b, and the second initialization transistor T4b may be disposed in a row along the second direction DR2. In an embodiment, the second data writing transistor T2b, the second emission control transistor T3b, the second driving transistor T1b, and the second initialization transistor T4b may be sequentially arranged in a direction opposite to the second direction DR2. However, embodiments are not necessarily limited thereto, and the positions of the transistors disposed in the second pixel circuit area PCAb may be interchanged with each other.

The second data writing transistor T2b may be adjacent to the first data writing transistor T2a in the first direction DR1, the second emission control transistor T3b may be adjacent to the first emission control transistor T3a in the first direction DR1, and the second initialization transistor T4b may be adjacent to the first initialization transistor T4a in the first direction DR1.

In an embodiment, the second driving transistor T1b may be adjacent to the first driving transistor T1a in a direction opposite to the second direction DR2. Specifically, the first driving transistor T1a may be positioned in an N-th row (where N is a natural number) parallel to the first direction DR1, and the second driving transistor T1b may be positioned in an (N+1)-th row parallel to the first direction DR1 and adjacent to the N-th row in the direction opposite to the second direction DR2. However, embodiments are not necessarily limited thereto, and the positions of the first driving transistor T1a and the second driving transistor T1b may be interchanged with each other.

In an embodiment, the first driving transistor T1a may extend from the first pixel circuit area PCAa to the second pixel circuit area PCAb, and the second driving transistor T1b may extend from the second pixel circuit area PCAb to the first pixel circuit area PCAa. That is, each of the first driving transistor T1a and the second driving transistor T1b may be disposed in both the first pixel circuit area PCAa and the second pixel circuit area PCAb.

Here, each of the first and second driving transistors T1a and T1b may correspond to the first transistor T1 in FIG. 3, each of the first and second data writing transistors T2a and T2b may correspond to the second transistor T2 in FIG. 3, each of the first and second emission control transistors T3a and T3b may correspond to the third transistor T3 in FIG. 3, and each of the first and second initialization transistors T4a and T4b may correspond to the fourth transistor T4 in FIG. 3.

That is, the first and second driving transistors T1a and T1b may generate a driving current, and the first and second emission control transistors T3a and T3b may receive a driving voltage (e.g., ELVDD in FIG. 3) in response to an emission control signal (e.g., EM in FIG. 3). In addition, each of the first and second data writing transistors T2a and T2b may receive a first data voltage and a second data voltage in response to a first gate signal (e.g., GW in FIG. 3), and each of the first and second initialization transistors T4a and T4b may receive a first initialization voltage and a second initialization voltage in response to a second gate signal (e.g., EB in FIG. 3). The first and second data voltages may be applied through different data lines, and the first and second initialization voltages may be applied through different initialization lines.

The first driving transistor T1a, the first data writing transistor T2a, the first emission control transistor T3a, and the first initialization transistor T4a may include the first, second, third, and fourth active portions A1a, A2a, A3a, and A4a of the substrate SUB spaced apart from each other, respectively. The second driving transistor T1b, the second data writing transistor T2b, the second emission control transistor T3b, and the second initialization transistor T4b may include fifth, sixth, seventh, and eighth active portions A1b, A2b, A3b, and A4b of the substrate SUB spaced apart from each other, respectively. In an embodiment, each of the first, second, third, fourth, fifth, sixth, seventh, and eighth active portions A1a, A2a, A3a, A4a, A1b, A2b, A3b, and A4b may extend in the first direction DR1.

In an embodiment, the second active portion A2a, the third active portion A3a, the first active portion A1a, and the fourth active portion A4a may be sequentially disposed in the direction opposite to the second direction DR2. In addition, the sixth active portion A2b, the seventh active portion A3b, the fifth active portion A1b, and the eighth active portion A4b may be sequentially disposed in the direction opposite to the second direction DR2.

In an embodiment, the fifth active portion A1b may be adjacent to the first active portion A1a in the direction opposite to the second direction DR2. Specifically, the first active portion A1a may be positioned in an N-th row parallel to the first direction DR1, and the fifth active portion A1b may be positioned in an (N+1)-th row adjacent to the N-th row in the direction opposite to the second direction DR2. However, embodiments are not necessarily limited thereto, and the positions of the first active portion A1a and the fifth active portion A1b may be interchanged with each other.

In an embodiment, each of the first active portion A1a and the fifth active portion A1b may be disposed in the first pixel circuit area PCAa and the second pixel circuit area PCAb.

The first active region A1a may include a first source region SR1a, a first drain region DR1a, and a first channel region CH1a between the first source region SR1a and the first drain region DR1a. For example, the first source region SR1a and the first drain region DR1a may be doped with p-type impurities. The first source region SR1a may be a source electrode of the first driving transistor T1a, and the first drain region DR1a may be a drain electrode of the first driving transistor T1a.

The second active region A2a may include a second source region SR2a, a second drain region DR2a, and a second channel region CH2a between the second source region SR2a and the second drain region DR2a. For example, the second source region SR2a and the second drain region DR2a may be doped with p-type impurities. The second source region SR2a may be a source electrode of the first data write transistor T2a, and the second drain region DR2a may be a drain electrode of the first data write transistor T2a.

The third active region A3a may include a third source region SR3a, a third drain region DR3a, and a third channel region CH3a between the third source region SR3a and the third drain region DR3a. For example, the third source region SR3a and the third drain region DR3a may be doped with p-type impurities. The third source region SR3a may be a source electrode of the first emission control transistor T3a, and the third drain region DR3a may be a drain electrode of the first emission control transistor T3a.

The fourth active region A4a may include a fourth source region SR4a, a fourth drain region DR4a, and a fourth channel region CH4a between the fourth source region SR4a and the fourth drain region DR4a. For example, the fourth source region SR4a and the fourth drain region DR4a may be doped with p-type impurities. The fourth source region SR4a may be a source electrode of the first initialization transistor T4a, and the fourth drain region DR4a may be a drain electrode of the first initialization transistor T4a.

The fifth active region A1b may include a fifth source region SR1b, a fifth drain region DR1b, and a fifth channel region CH1b between the fifth source region SR1b and the fifth drain region DR1b. For example, the fifth source region SR1b and the fifth drain region DR1b may be doped with p-type impurities. The fifth source region SR1b may be a source electrode of the second driving transistor T1b, and the fifth drain region DR1b may be a drain electrode of the second driving transistor T1b.

The sixth active region A2b may include a sixth source region SR2b, a sixth drain region DR2b, and a sixth channel region CH2b between the sixth source region SR2b and the sixth drain region DR2b. For example, the sixth source region SR2b and the sixth drain region DR2b may be doped with p-type impurities. The sixth source region SR2b may be a source electrode of the second data write transistor T2b, and the sixth drain region DR2b may be a drain electrode of the second data write transistor T2b.

The seventh active region A3b may include a seventh source region SR3b, a seventh drain region DR3b, and a seventh channel region CH3b between the seventh source region SR3b and the seventh drain region DR3b. For example, the seventh source region SR3b and the seventh drain region DR3b may be doped with p-type impurities. The seventh source region SR3b may be a source electrode of the second emission control transistor T3b, and the seventh drain region DR3b may be a drain electrode of the second emission control transistor T3b.

The eighth active region A4b may include an eighth source region SR4b, an eighth drain region DR4b, and an eighth channel region CH4b between the eighth source region SR4b and the eighth drain region DR4b. For example, the eighth source region SR4b and the eighth drain region DR4b may be doped with p-type impurities. The eighth source region SR4b may be a source electrode of the second initialization transistor T4b, and the eighth drain region DR4b may be a drain electrode of the second initialization transistor T4b.

The first driving transistor T1a, which extends across multiple circuit areas (i.e., both the first pixel circuit area PCAa and the second pixel circuit area PCAb), may have a channel length that is longer than that of each of the first data writing transistor T2a, the first emission control transistor T3a and the first initialization transistor T4a which are provided in a single pixel circuit area (i.e., the first pixel circuit area PCAa). Similarly, the second driving transistor T1b, which extends across multiple circuit areas (i.e., both the first pixel circuit area PCAa and the second pixel circuit area PCAb), may have a channel length that is longer than that of each of the second data writing transistor T2b, the second emission control transistor T3b and the second initialization transistor T4b which are provided in a single pixel circuit area (i.e., the second pixel circuit area PCAb).

In an embodiment, an element isolating layer including an insulating material may be formed between the first, second, third, fourth, fifth, sixth, seventh, and eighth active portions A1a, A2a, A3a, A4a, A1b, A2b, A3b, and A4b.

The first driving transistor T1a, the first data write transistor T2a, the first emission control transistor T3a, and the first initialization transistor T4a may further include first, second, third, and fourth gate electrodes GE1a, GE2a, GE3a, and GE4a spaced apart from each other, respectively. In addition, the second driving transistor T1b, the second data write transistor T2b, the second emission control transistor T3b, and the second initialization transistor T4b may further include fifth, sixth, seventh, and eighth gate electrodes GE1b, GE2b, GE3b, and GE4b spaced apart from each other. In an embodiment, each of the first, second, third, fourth, fifth, sixth, seventh, and eighth gate electrodes GE1a, GE2a, GE3a, GE4a, GE1b, GE2b, GE3b, and GE4b may extend in the first direction DR1.

In an embodiment, each of the first gate electrode GE1a and the fifth gate electrode GE1b may be disposed in the first pixel circuit area PCAa and the second pixel circuit area PCAb.

The first gate electrode GE1a may overlap the first channel region CH1a of the first active region A1a in the plan view (i.e., along the third direction DR3). The first gate electrode GE1a may be a gate electrode of the first driving transistor T1a. Likewise, the fifth gate electrode GE1b may overlap the fifth channel region CH1b of the fifth active region A1b in the plan view (i.e., along the third direction DR3). The fifth gate electrode GE1b may be a gate electrode of the second driving transistor T1b.

The second gate electrode GE2a may overlap the second channel region CH2a of the second active region A2a in the plan view (i.e., along the third direction DR3). The second gate electrode GE2a may be a gate electrode of the first data write transistor T2a. Likewise, the sixth gate electrode GE2b may overlap the sixth channel region CH2b of the sixth active region A2b in the plan view (i.e., along the third direction DR3). The sixth gate electrode GE2b may be a gate electrode of the second data write transistor T2b.

The third gate electrode GE3a may overlap the third channel region CH3a of the third active region A3a in the plan view (i.e., along the third direction DR3). The third gate electrode GE3a may be a gate electrode of the first emission control transistor T3a. Likewise, the seventh gate electrode GE3b may overlap the seventh channel region CH3b of the seventh active region A3b in the plan view (i.e., along the third direction DR3). The seventh gate electrode GE3b may be a gate electrode of the second emission control transistor T3b.

The fourth gate electrode GE4a may overlap the fourth channel region CH4a of the fourth active region A4a in the plan view (i.e., along the third direction DR3). The fourth gate electrode GE4a may be a gate electrode of the first initialization transistor T4a. Likewise, the eighth gate electrode GE4b may overlap the eighth channel region CH4b of the eighth active region A4b in the plan view (i.e., along the third direction DR3). The eighth gate electrode GE4b may be a gate electrode of the second initialization transistor T4b.

The first gate electrode GE1a may include a first contact portion CPa, and the fifth gate electrode GE1b may include a second contact portion CPb. The first contact portion CPa may be electrically connected to the first data write transistor T2a through a first connection line CLa, and the second contact portion CPb may be electrically connected to the second data write transistor T2b through a second connection line CLb. For example, the first connection line CLa may directly connect the first contact portion CPa and the first data write transistor T2a or may be connected through another conductive pattern. Likewise, the second connection line CLb may directly connect the second contact portion CPb and the second data write transistor T2b or may be connected through another conductive pattern.

In an embodiment, the first contact portion CPa may be positioned in the first pixel circuit area PCAa, and the second contact portion CPb may be positioned in the second pixel circuit area PCAb.

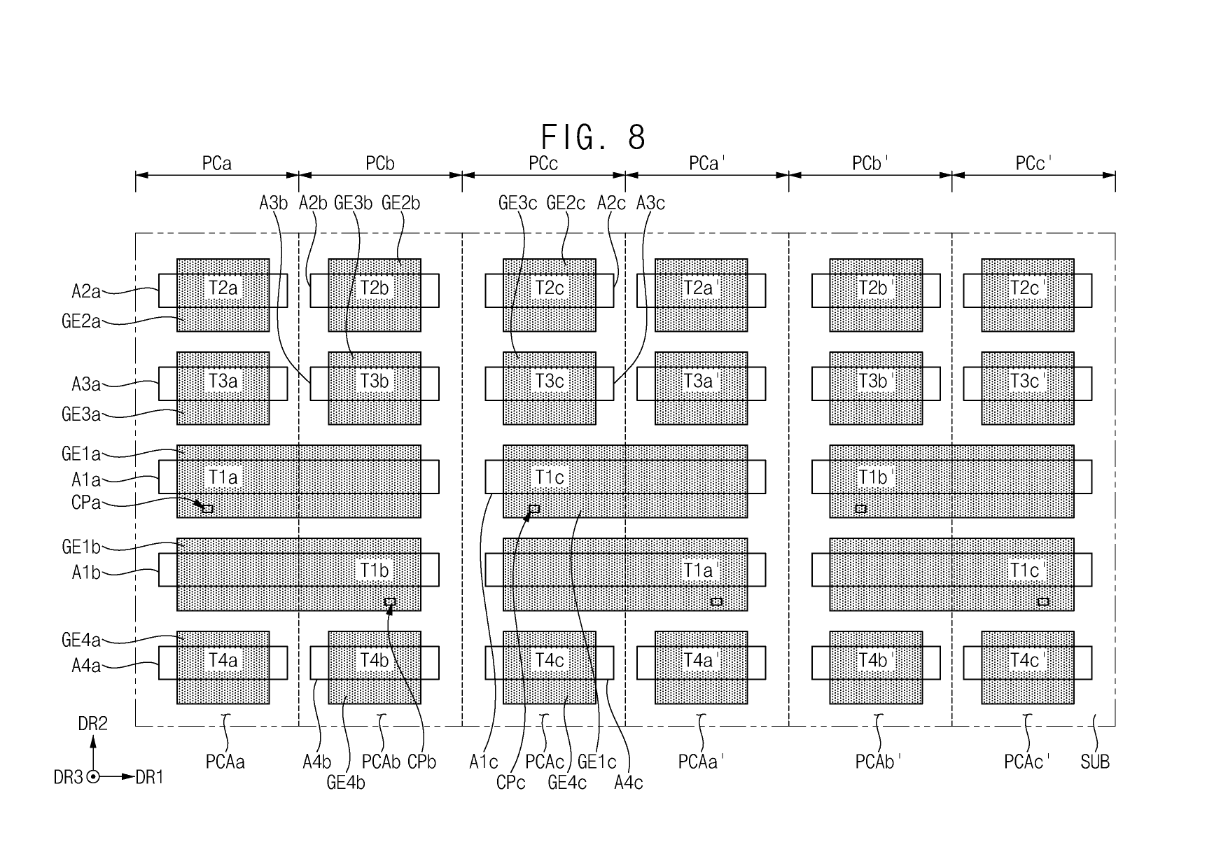

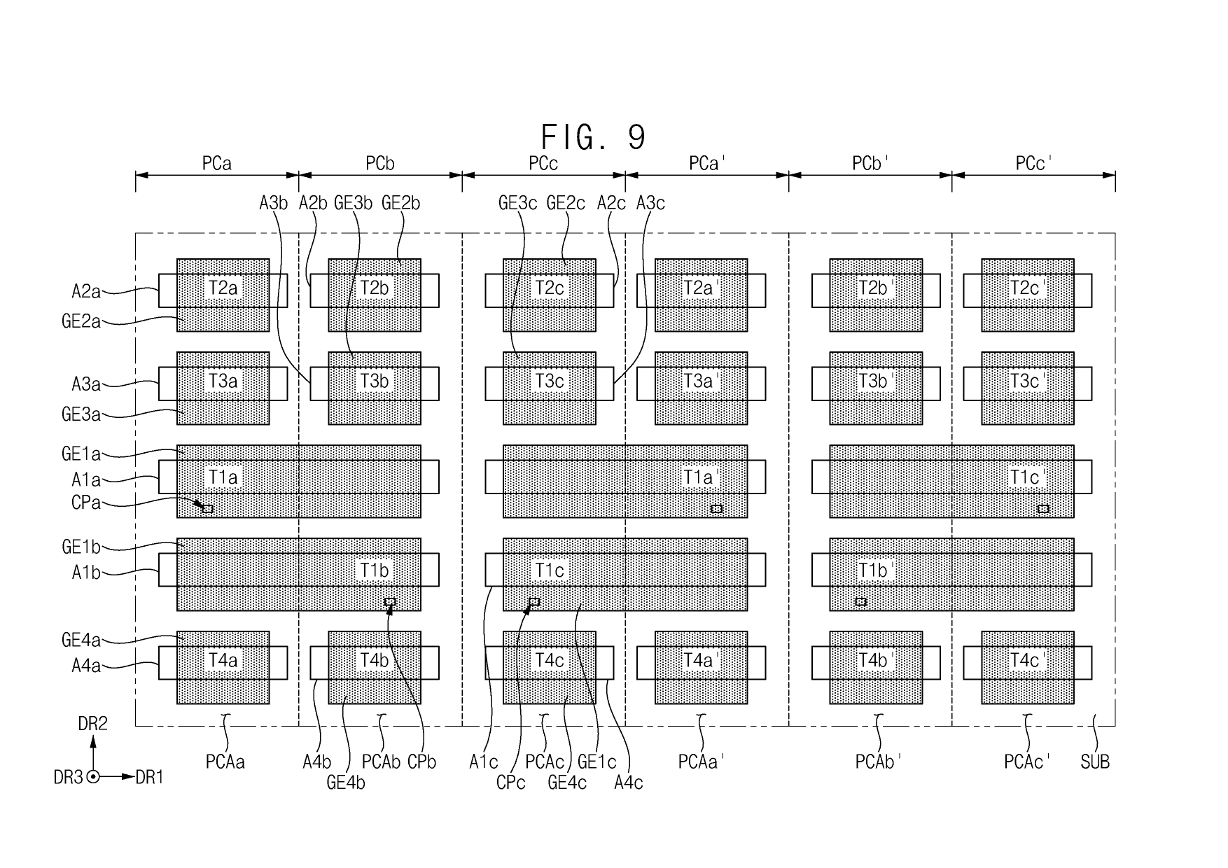

FIG. 8 is a layout view illustrating an example of first, second, third, fourth, fifth, and sixth pixel driving circuit parts included in the transistor array of FIG. 5. FIG. 9 is a layout view illustrating an example of first, second, third, fourth, fifth, and sixth pixel driving circuit parts included in the transistor array of FIG. 5.

Hereinafter, the arrangement structure of the transistors included in the first pixel driving circuit part PCa and the second pixel driving circuit part PCb described with reference to FIGS. 8 and 9 may be the same as the arrangement structure of the transistors included in the first pixel driving circuit part PCa and the second pixel driving circuit part PCb described with reference to FIGS. 6 and 7. Therefore, redundant description will be omitted or simplified.

Referring to FIGS. 8 and 9, the third pixel driving circuit part PCc may include a third driving transistor T1c, a third data write transistor T2c, a third emission control transistor T3c, and a third initialization transistor T4c disposed in the third pixel circuit area PCAc.

Here, the third driving transistor T1c may correspond to the first transistor T1 in FIG. 3, the third data write transistor T2c may correspond to the second transistor T2 in FIG. 3, the third emission control transistor T3c may correspond to the third transistor T3 in FIG. 3, and the third initialization transistor T4c may correspond to the fourth transistor T4 in FIG. 3.

The fourth, fifth, and sixth pixel driving circuit parts PCa’, PCb’, and PCc’ may include fourth, fifth, and sixth driving transistors T1a’, T1b’, and T1c’, fourth, fifth, and sixth data write transistors T2a’, T2b’, and T2c’, fourth, fifth, and sixth emission control transistors T3a’, T3b’, and T3c’, and fourth, fifth, and sixth initialization transistors T4a’, T4b’, and T4c’, respectively. The fourth, fifth, and sixth driving transistors T1a’, T1b’, and T1c’ may respectively include substantially the same components as the corresponding first, second, and third driving transistors T1a, T1b, and T1c, the fourth, fifth, and sixth data write transistors T2a’, T2b’, and T2c’ may respectively include substantially the same components as the corresponding the first, second, and third data write transistors T2a, T2b, and T2c, the fourth, fifth, and sixth emission control transistors T3a’, T3b’, and T3c’ may respectively include substantially the same components as the corresponding first, second, and third emission control transistors T3a, T3b, and T3c, and the fourth, fifth, and sixth initialization transistors T4a’, T4b’, and T4c’ may respectively include substantially the same components as the corresponding first, second, and third initialization transistors T4a, T4b, and T4c.

The first, second, third, fourth, fifth, and sixth data write transistors T2a, T2b, T2c, T2a’, T2b’, and T2c’ may be sequentially disposed along the first direction DR1. The first, second, third, fourth, fifth, and sixth emission control transistors T3a, T3b, T3c, T3a’, T3b’, and T3c’ may be sequentially disposed along the first direction DR1. The first, second, third, fourth, fifth, and sixth initialization transistors T4a, T4b, T4c, T4a’, T4b’, and T4c’ may be sequentially disposed along the first direction DR1.

In an embodiment, each of the third driving transistor T1c and the fourth driving transistor T1a’ may be disposed in the third pixel circuit area PCAc and the fourth pixel circuit area PCAa’ and each of the fifth driving transistor T1b’ and the sixth driving transistor T1c’ may be disposed in the fifth pixel circuit area PCAb’ and the sixth pixel circuit area PCAc’.

As illustrated in FIG. 8, in an embodiment, the first driving transistor T1a, the third driving transistor T1c, and the fifth driving transistor T1b’ may be positioned in the N-th row (where N is a natural number) parallel to the first direction DR1, and the second driving transistor T1b, the fourth driving transistor T1a’, and the sixth driving transistor T1c’ may be positioned in the (N+1)-th row parallel to the first direction DR1 and adjacent to the N-th row in the direction opposite to the second direction DR2. That is, the third driving transistor T1c may be adjacent to the fourth driving transistor T1a’ in the second direction DR2, and the fifth driving transistor T1b’ may be adjacent to the sixth driving transistor T1c’ in the second direction DR2.

However, embodiments are not necessarily limited thereto. As illustrated in FIG. 9, in an embodiment, the first driving transistor T1a, the fourth driving transistor T1a’, and the sixth driving transistor T1c’ may be positioned in the N-th row parallel to the first direction DR1, and the second driving transistor T1b, the third driving transistor T1c, and the fifth driving transistor T1b’ may be positioned in the (N+1)-th row. That is, the third driving transistor T1c may be adjacent to the fourth driving transistor T1a’ in the direction opposite to the second direction DR2, and the fifth driving transistor T1b’ may be adjacent to the sixth driving transistor T1c’ in the direction opposite to the second direction DR2.

The third driving transistor T1c, the third data write transistor T2c, the third emission control transistor T3c, and the third initialization transistor T4c may include the ninth, tenth, eleventh, and twelfth active portions A1c, A2c, A3c, and A4c of the substrate SUB and the ninth, tenth, eleventh, and twelfth gate electrodes GE1c, GE2c, GE3c, and GE4c, respectively.

Each of the ninth, tenth, eleventh, and twelfth active portions A1c, A2c, A3c, and A4c may include a source region, a drain region, and a channel region between the source region and the drain region. For example, the source region and the drain region may be doped with p-type impurities. The ninth, tenth, eleventh, and twelfth gate electrodes GE1c, GE2c, GE3c, and GE4c may overlap the channel regions of the ninth, tenth, eleventh, and twelfth active portions A1c, A2c, A3c, and A4c in the plan view (i.e., along the third direction DR3), respectively.

The ninth gate electrode GE1c may include a third contact portion CPc. The third contact portion CPc may be electrically connected to the third data write transistor T2c through a third connection line. In an embodiment, the third contact portion CPc may be positioned in the third pixel circuit area PCAc.

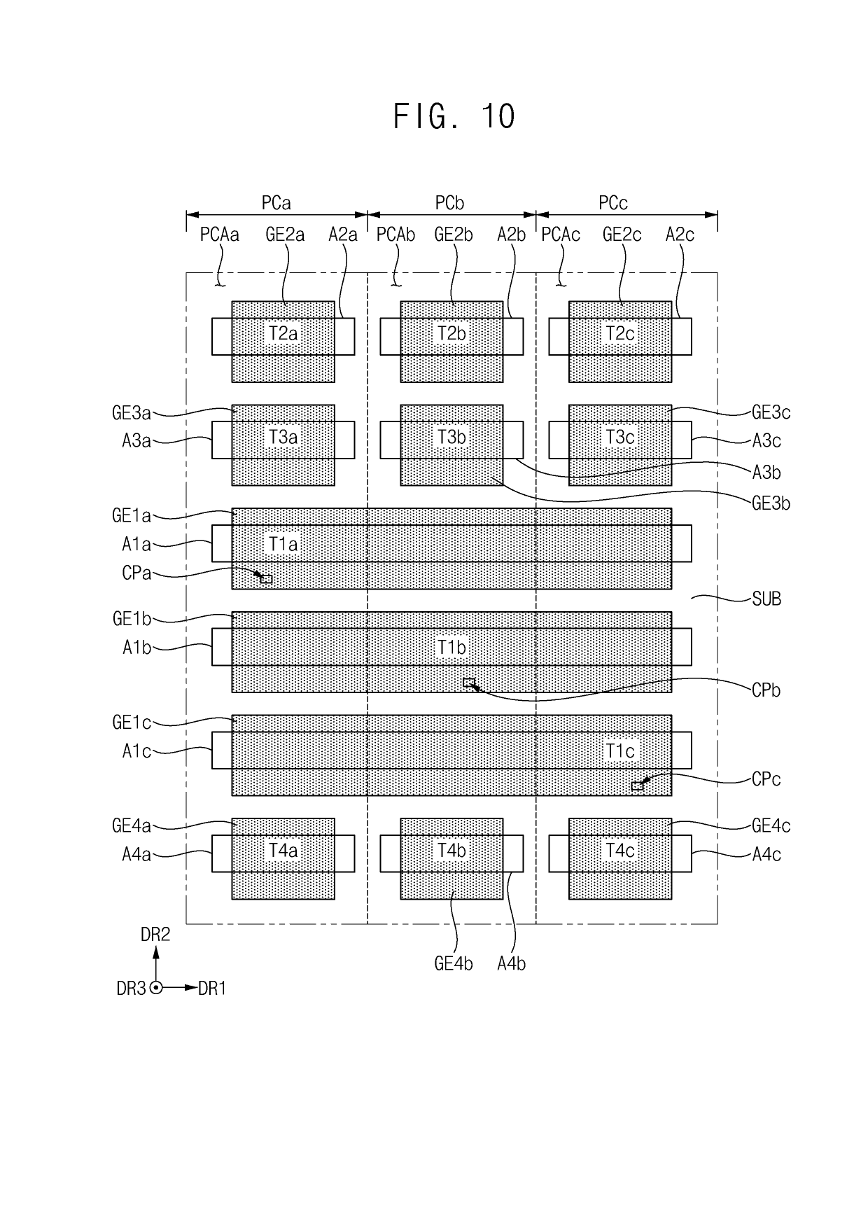

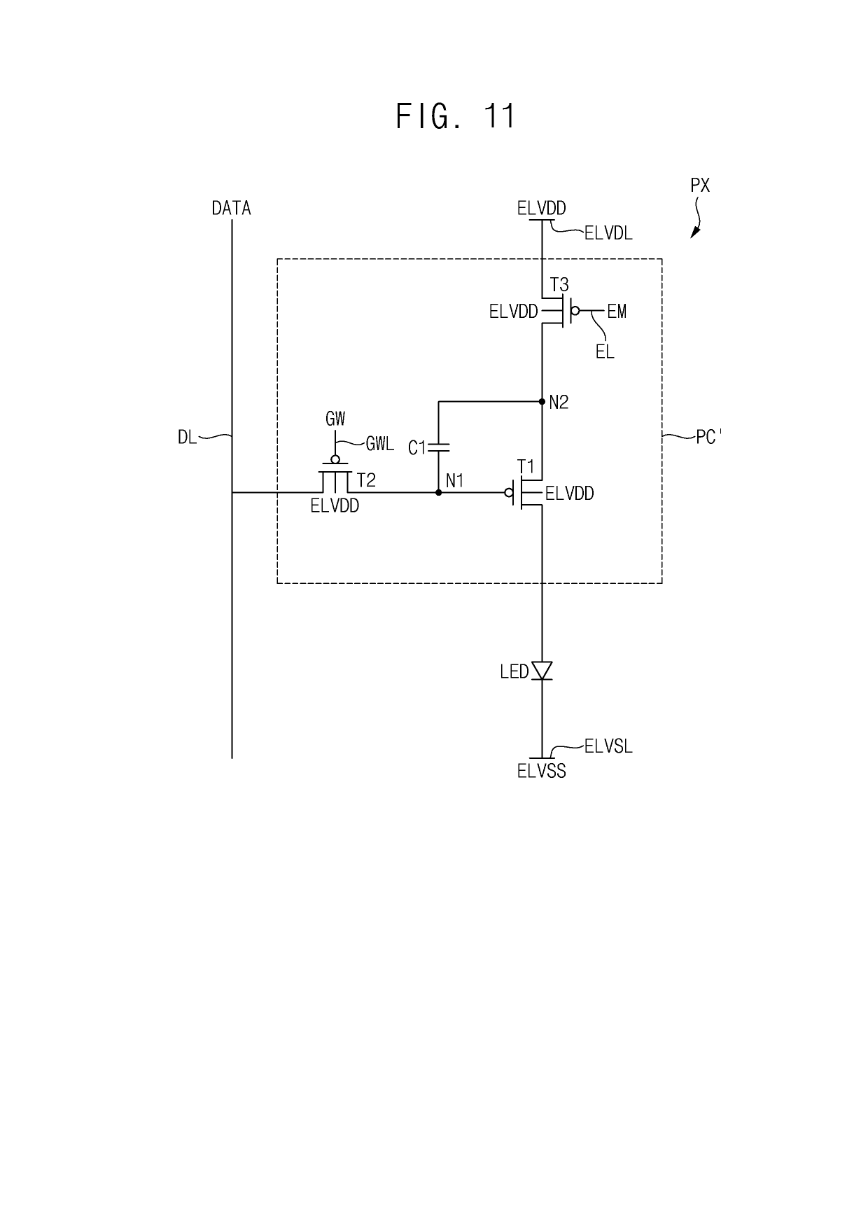

FIG. 10 is a layout view illustrating an example of first, second, and third pixel driving circuit parts included in the transistor array of FIG. 5.

Hereinafter, redundant descriptions of the contents described with reference to FIGS. 6, 7, 8, and 9 will be omitted or simplified. In addition, the following description of the first, second, and third pixel driving circuit parts PCa, PCb, and PCc may be substantially equally applied to the fourth, fifth, and sixth pixel driving circuit parts PCa’, PCb’, and PCc’ in FIG. 5.

Referring to FIG. 10, the first data write transistor T2a, the first emission control transistor T3a, the first driving transistor T1a, and the first initialization transistor T4a may be sequentially disposed along the direction opposite to the second direction DR2. However, embodiments are not necessarily limited thereto, and the positions of the transistors disposed in the first pixel circuit area PCAa may be interchanged with each other. The arrangement order of the transistors included in each of the second pixel driving circuit part PCb and the third pixel driving circuit part PCc in the direction opposite to the second direction DR2 may be the same as the arrangement order of the transistors included in the first pixel driving circuit part PCa in the direction opposite to the second direction DR2.

The first, second, and third data write transistors T2a, T2b, and T2c may be sequentially disposed along the first direction DR1, the first, second, and third emission control transistors T3a, T3b, and T3c may be sequentially disposed along the first direction DR1, and the first, second, and third initialization transistors T4a, T4b, and T4c may be sequentially disposed along the first direction DR1.

In an embodiment, the second driving transistor T1b may be adjacent to the first driving transistor T1a in the direction opposite to the second direction DR2, and the third driving transistor T1c may be adjacent to the second driving transistor T1b in the direction opposite to the second direction DR2. Specifically, the first driving transistor T1a, the second driving transistor T1b, and the third driving transistor T1c may be disposed in different rows parallel to the first direction DR1. However, embodiments are not necessarily limited thereto, and the positions of the first driving transistor T1a, the second driving transistor T1b, and the third driving transistor T1c may be interchanged with each other.

In an embodiment, each of the first driving transistor T1a, the second driving transistor T1b, and the third driving transistor T1c may be disposed in the first, second, and third pixel circuit areas PCAa, PCAb, and PCAc. In this case, each of the first active portion A1a and the first gate electrode GE1a of the first driving transistor T1a may be disposed in the first, second, and third pixel circuit areas PCAa, PCAb, and PCAc, each of the fifth active portion A1b and the fifth gate electrode GE1b of the second driving transistor T1b may be disposed in the first, second, and third pixel circuit areas PCAa, PCAb, and PCAc, and each of the ninth active portion A1c and the ninth gate electrode GE1c of the third driving transistor T1c may be disposed in the first, second, and third pixel circuit areas PCAa, PCAb, and PCAc.

FIG. 11 is a circuit view illustrating another example of the circuit structure of one pixel of FIG. 1. The pixel PX described with reference to FIG. 11 may be substantially the same as or similar to the pixel PX described with reference to FIG. 3, except that the fourth transistor T4, the second capacitor C2, and the third capacitor C3 are omitted. Therefore, redundant descriptions will be omitted or simplified.

Referring to FIG. 11, each pixel PX may include a pixel driving circuit part PC′ and a light-emitting element LED electrically connected to the pixel driving circuit part PC′. The pixel driving circuit part PC′ may generate a driving current, and the light-emitting element LED may generate light based on the driving current.

In an embodiment, the pixel driving circuit part PC′ may include a first transistor T1, a second transistor T2, a third transistor T3, and a first capacitor C1.

In an embodiment, the first transistor T1, the second transistor T2, the third transistor T3, and the fourth transistor T4 may all be MOSFET formed through a semiconductor process.

In an embodiment, the first transistor T1, the second transistor T2, and the third transistor T3 may all be PMOS transistors. However, embodiments are not necessarily limited thereto, and some of the first transistor T1, the second transistor T2, and the third transistor T3 may be PMOS transistors, and the others may be NMOS transistors.

The first transistor T1 may include a gate electrode, a source electrode, and a drain electrode. The gate electrode of the first transistor T1 may be connected to a first node N1. The source electrode of the first transistor T1 may be connected to a second node N2. The drain electrode of the first transistor T1 may be connected to the anode electrode of the light-emitting element LED. The first transistor T1 may provide the driving current to the light-emitting element LED. The first transistor T1 may be referred to as a driving transistor.

The second transistor T2 may include a gate electrode, a source electrode, and a drain electrode. A first gate signal line GWL which receives a first gate signal GW may be connected to the gate electrode of the second transistor T2. A data line DL which receives a data voltage DATA may be connected to the source electrode of the second transistor T2. The drain electrode of the second transistor T2 may be connected to the first node N1. That is, the second transistor T2 may be electrically connected to the first transistor T1. The second transistor T2 may be turned on or off in response to the first gate signal GW. The second transistor T2 may be referred to as a data write transistor.

The third transistor T3 may include a gate electrode, a source electrode, and a drain electrode. The gate electrode of the third transistor T3 may be connected to an emission control line EL which receives an emission control signal EM. The source electrode of the third transistor T3 may be connected to a driving voltage line ELVDL which receives a driving voltage ELVDD. The drain electrode of the third transistor T3 may be connected to the second node N2. That is, the third transistor T3 may be electrically connected to the first transistor T1. The third transistor T3 may be turned on or off in response to the emission control signal EM. The third transistor T3 may be referred to as an emission control transistor.

Each of the first, second, and third transistors T1, T2, and T3 may further include a body electrode. The body electrode of each of the first, second, and third transistors T1, T2, and T3 may receive the driving voltage ELVDD. For example, the body electrode of each of the first, second, and third transistors T1, T2, and T3 may be connected to the driving voltage line ELVDL which receives the driving voltage ELVDD. Alternatively, a separate power supply other than the driving voltage ELVDD may be applied to the body electrode of each of the first, second, and third transistors T1, T2, and T3.

The first capacitor C1 may include a first electrode and a second electrode. The first electrode of the first capacitor C1 may be connected to the first node N1. The second electrode of the first capacitor C1 may be connected to the second node N2.

The light-emitting element LED may include an anode electrode and a cathode electrode. The anode electrode of the light-emitting element LED may be connected to the drain electrode of the first transistor T1. A common voltage line ELVSL which receives a common voltage ELVSS may be connected to the cathode electrode of the light-emitting element LED. The common voltage ELVSS may have a voltage level lower than the driving voltage ELVDD.

Although FIG. 11 illustrates one pixel driving circuit part PC′ including three transistors and one capacitor, embodiments are not necessarily limited thereto.

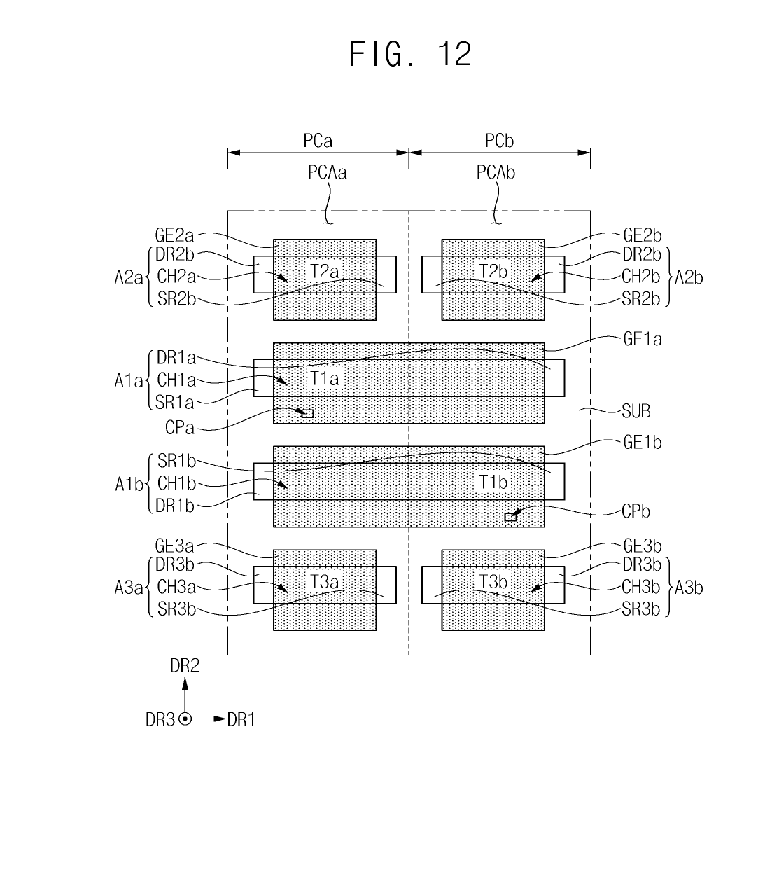

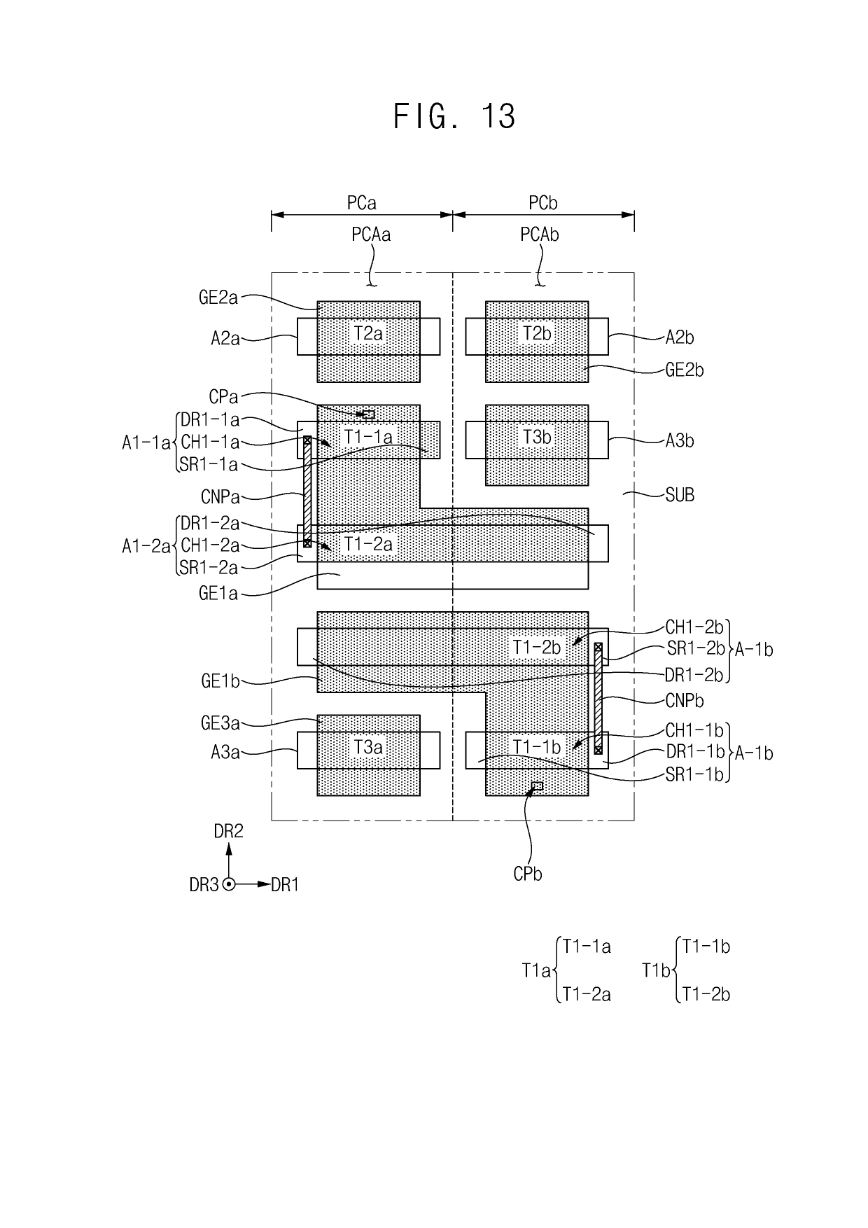

FIG. 12 is a layout view illustrating another example of a first pixel driving circuit part and a second pixel driving circuit part included in the transistor array of FIG. 5.

Hereinafter, the first and second pixel driving circuit parts PCa and PCb described with reference to FIG. 12 may be substantially the same as or similar to the first and second pixel driving circuit parts PCa and PCb described with reference to FIGS. 6 and 7, except that the first and second initialization transistors T4a and T4b are omitted. Therefore, redundant descriptions will be omitted or simplified.

In addition, the following description of the first and second pixel driving circuit parts PCa and PCb may be substantially equally applied to the third and fourth pixel driving circuit parts PCc and PCa’ and the fifth and sixth pixel driving circuit parts PCb’ and PCc’ in FIG. 5.

Referring to FIG. 12, the first pixel driving circuit part PCa may include a first driving transistor T1a, a first data writing transistor T2a, and a first emission control transistor T3a disposed in the first pixel circuit area PCAa. Likewise, the second pixel driving circuit part PCb may include a second driving transistor T1b, a second data writing transistor T2b, and a second emission control transistor T3b disposed in the second pixel circuit area PCAb.

The first driving transistor T1a, the first data writing transistor T2a, and the first emission control transistor T3a may be disposed in a row along the second direction DR2. In an embodiment, the first data writing transistor T2a, the first driving transistor T1a, and the first emission control transistor T3a may be sequentially disposed along the direction opposite to the second direction DR2. However, embodiments are not necessarily limited thereto, and the positions of the transistors disposed in the first pixel circuit area PCAa may be interchanged with each other. The arrangement order of the transistors included in the second pixel driving circuit part PCb in the direction opposite to the second direction DR2 may be the same as the arrangement order of the transistors included in the first pixel driving circuit part PCa in the direction opposite to the second direction DR2.

The second data writing transistor T2b may be adjacent to the first data writing transistor T2a in the first direction DR1, and the second emission control transistor T3b may be adjacent to the first emission control transistor T3a in the first direction DR1.

In an embodiment, the second driving transistor T1b may be adjacent to the first driving transistor T1a in the direction opposite to the second direction DR2. Specifically, the first driving transistor T1a may be positioned in the N-th row parallel to the first direction DR1 (where N is a natural number), and the second driving transistor T1b may be positioned in the (N+1)-th row parallel to the first direction DR1 and adjacent to the N-th row in the direction opposite to the second direction DR2. However, embodiments are not necessarily limited thereto, and the positions of the first and second driving transistors T1a and T1b may be interchanged with each other.

In an embodiment, the first driving transistor T1a may extend from the first pixel circuit area PCAa to the second pixel circuit area PCAb, and the second driving transistor T1b may extend from the second pixel circuit area PCAb to the first pixel circuit area PCAa. That is, each of the first driving transistor T1a and the second driving transistor T1b may be disposed in both the first pixel circuit area PCAa and the second pixel circuit area PCAb.

Each of the first and second pixel driving circuit parts PCa and PCb may correspond to the pixel driving circuit part PC’ in FIG. 11. That is, the first and second driving transistors T1a and T1b may correspond to the first transistor T1 in FIG. 11, the first and second data writing transistors T2a and T2b may correspond to the second transistor T2 in FIG. 11, and the first and second emission control transistors T3a and T3b may correspond to the third transistor T3 in FIG. 11.

That is, the first and second driving transistors T1a and T1b may generate the driving current, and the first and second emission control transistors T3a and T3b may receive a driving voltage (e.g., ELVDD in FIG. 11) in response to an emission control signal (e.g., EM in FIG. 11). In addition, the first and second data writing transistors T2a and T2b may receive a first data voltage and a second data voltage in response to a first gate signal (e.g., GW in FIG. 11), respectively. The first and second data voltages may be supplied through different data lines.

The first driving transistor T1a, the first data writing transistor T2a, and the first emission control transistor T3a may include first, second, and third active portions A1a, A2a, and A3a of the substrate SUB spaced apart from each other, respectively. Likewise, the second driving transistor T1b, the second data writing transistor T2b, and the second emission control transistor T3b may include fifth, sixth, and seventh active portions A1b, A2b, and A3b of the substrate SUB spaced apart from each other, respectively. In an embodiment, each of the first, second, and third active portions A1a, A2a, and A3a and each of the fifth, sixth, and seventh active portions A1b, A2b, and A3b may extend in the first direction DR1.

The first driving transistor T1a, the first data writing transistor T2a, and the first emission control transistor T3a may further include first, second, and third gate electrodes GE1a, GE2a, and GE3a spaced apart from each other, respectively. Likewise, the second driving transistor T1b, the second data writing transistor T2b, and the second emission control transistor T3b may further include fifth, sixth, and seventh gate electrodes GE1b, GE2b, and GE3b spaced apart from each other, respectively.

The first, second, and third active portions A1a, A2a, and A3a may include a corresponding source region SR1a, SR2a, and SR3a, a corresponding drain region DR1a, DR2a, and DR3a, and a corresponding channel region CH1a, CH2a, and CH3a between the source region SR1a, SR2a, and SR3a and the drain region DR1a, DR2a, and DR3a, respectively. For example, the source regions SR1a, SR2a, and SR3a and the drain regions DR1a, DR2a, and DR3a may be doped with p-type impurities. The first, second, and third gate electrodes GE1a, GE2a, and GE3a may overlap the corresponding channel regions CH1a, CH2a, and CH3a in the plan view (i.e., along the third direction DR3), respectively.

The fifth, sixth, and seventh active portions A1b, A2b, and A3b may include a corresponding source region SR1b, SR2b, and SR3b, a corresponding drain region DR1b, DR2b, and DR3b, and a corresponding channel region CH1b, CH2b, and CH3b between the source region SR1a, SR2a, and SR3a and the drain region DR1a, DR2a, and DR3a. For example, the source regions SR1b, SR2b, and SR3b and the drain regions DR1b, DR2b, and DR3b may be doped with p-type impurities. The fifth, sixth, and seventh gate electrodes GE1b, GE2b, and GE3b may overlap the corresponding channel regions CH1b, CH2b, and CH3b in the plan view (i.e., along the third direction DR3), respectively.

In an embodiment, each of the first active portion A1a and the first gate electrode GE1a of the first driving transistor T1a may be disposed in the first and second pixel circuit areas PCAa and PCAb. Each of the fifth active portion A1b and the fifth gate electrode GE1b of the second driving transistor T1b may be disposed in the first and second pixel circuit areas PCAa and PCAb.

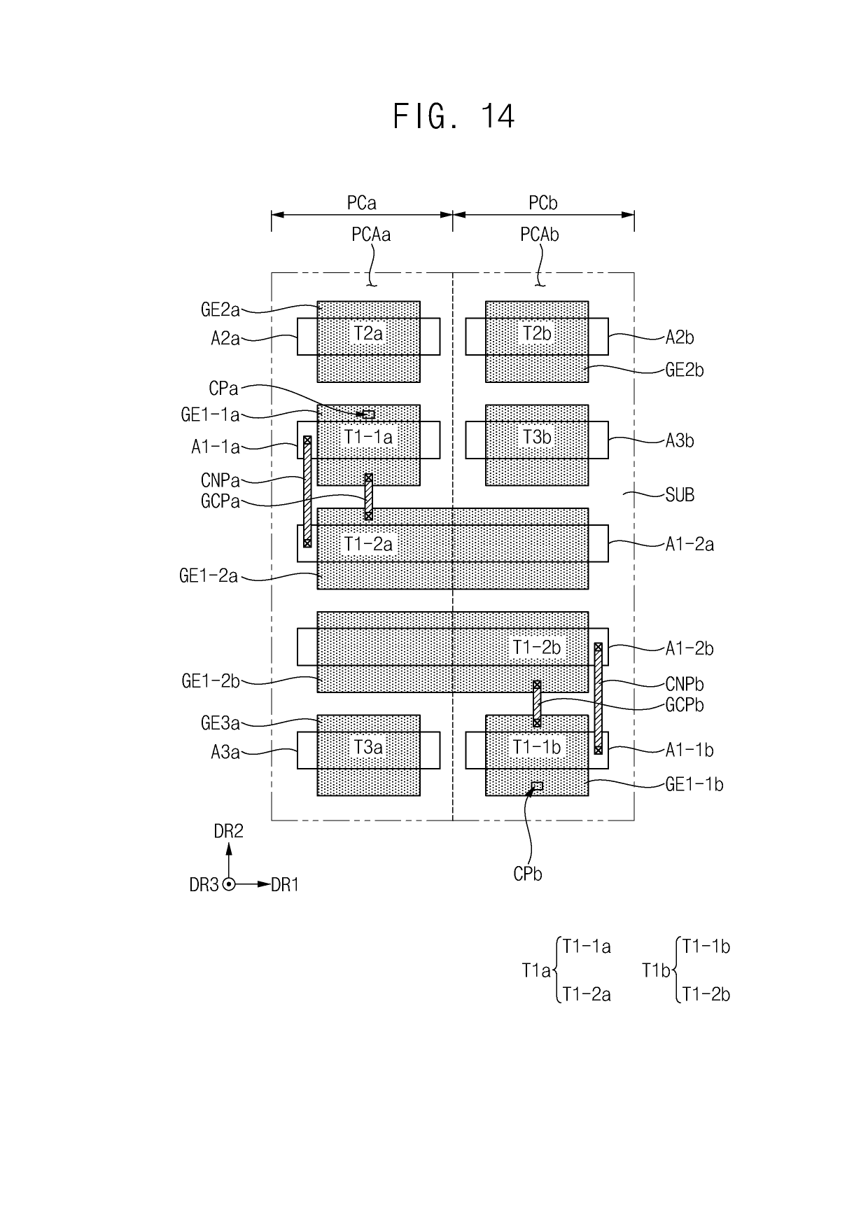

FIG. 13 is a layout view illustrating another example of a first pixel driving circuit part and a second pixel driving circuit part included in the transistor array of FIG. 5.

Hereinafter, the first and second pixel driving circuit parts PCa and PCb described with reference to FIG. 13 may be substantially the same as or similar to the first and second pixel driving circuit parts PCa and PCb described with reference to FIG. 12, except for the structures of the first and second driving transistors T1a and T1b. Therefore, redundant descriptions will be omitted or simplified.

Referring to FIG. 13, the first driving transistor T1a, the first data writing transistor T2a, and the first emission control transistor T3a may be disposed in a row along the second direction DR2. In an embodiment, the first data writing transistor T2a, the first driving transistor T1a, and the first emission control transistor T3a may be sequentially disposed along the direction opposite to the second direction DR2. However, embodiments are not necessarily limited thereto, and the positions of the transistors disposed in the first pixel circuit area PCAa may be interchanged with each other.

The second driving transistor T1b, the second data writing transistor T2b, and the second emission control transistor T3b may also be disposed in a row along the second direction DR2. In an embodiment, the second data writing transistor T2b, the second emission control transistor T3b, and the second driving transistor T1b may be sequentially disposed along the direction opposite to the second direction DR2. However, embodiments are not necessarily limited thereto, and the positions of the transistors disposed in the second pixel circuit area PCAb may be interchanged with each other.

In an embodiment, the first driving transistor T1a may include a first-first driving transistor T1-1a disposed in the first pixel circuit area PCAa, and a first-second driving transistor T1-2a disposed in the first and second pixel circuit areas PCAa and PCAb, connected to the first-first driving transistor T1-1a, and adjacent to the first-first driving transistor T1-1a in the direction opposite to the second direction DR2. Similarly, the second driving transistor T1b may include a second-first driving transistor T1-1b disposed in the second pixel circuit area PCAb, and a second-second driving transistor T1-2b disposed in the first and second pixel circuit areas PCAa and PCAb, connected to the second-first driving transistor T1-1b, and adjacent to the second-first driving transistor T1-1b in the second direction DR2.

The first-first driving transistor T1-1a, the first-second driving transistor T1-2a, the second-first driving transistor T1-1b, and the second-second driving transistor T1-2b may include a first-first active portion A1-1a, a first-second active portion A1-2a, a fifth-first active portion A1-1b, and a fifth-second active portion A1-2b of the substrate SUB spaced apart from each other, respectively. In an embodiment, each of the active portions A1-1a, A1-2a, A1-1b, and A1-2b may extend in the first direction DR1.

In an embodiment, the first-first active portion A1-1a may be disposed in the first pixel circuit area PCAa, and the first-second active portion A1-2a may be disposed in both of the first and second pixel circuit areas PCAa and PCAb. In addition, the fifth-first active portion A1-1b may be disposed in the second pixel circuit area PCAb, and the fifth-second active portion A1-2b may be disposed in both of the first and second pixel circuit areas PCAa and PCAb.

The first-first active portion A1-1a may include a first-first source region SR1-1a, a first-first drain region DR1-1a, and a first-first channel region CH1-1a between the first-first source region SR1-1a and the first-first drain region DR1-1a. For example, the first-first source region SR1-1a and the first-first drain region DR1-1a may be doped with p-type impurities. The first-first source region SR1-1a and the first-first drain region DR1-1a may be a source electrode and a drain electrode of the first-first driving transistor T1-1a, respectively.

The first-second active portion A1-2a may include a first-second source region SR1-2a, a first-second drain region DR1-2a, and a first-second channel region CH1-2a between the first-second source region SR1-2a and the first-second drain region DR1-2a. For example, the first-second source region SR1-2a and the first-second drain region DR1-2a may be doped with p-type impurities. The first-second source region SR1-2a and the first-second drain region DR1-2a may be a source electrode and a drain electrode of the first-second driving transistor T1-2a, respectively.

The fifth-first active portion A1-1b may include a fifth-first source region SR1-1b, a fifth-first drain region DR1-1b, and a fifth-first channel region CH1-1b between the fifth-first source region SR1-1b and the fifth-first drain region DR1-1b. For example, the fifth-first source region SR1-1b and the fifth-first drain region DR1-1b may be doped with p-type impurities. The fifth-first source region SR1-1b and the fifth-first drain region DR1-1b may be a source electrode and a drain electrode of the second-first driving transistor T1-1b, respectively.

The fifth-second active portion A1-2b may include a fifth-second source region SR1-2b, a fifth-second drain region DR1-2b, and a fifth-second channel region CH1-2b between the fifth-second source region SR1-2b and the fifth-second drain region DR1-2b. For example, the fifth-second source region SR1-2b and the fifth-second drain region DR1-2b may be doped with p-type impurities. The fifth-second source region SR1-2b and the fifth-second drain region DR1-2b may be a source electrode and a drain electrode of the second-second driving transistor T1-2b, respectively.

The first-first and first-second driving transistors T1-1a and T1-2a may further include a first-first gate electrode and a first-second gate electrode, respectively, and the second-first and second-second driving transistors T1-1b and T1-2b may further include a fifth-first gate electrode and a fifth-second gate electrode, respectively.

The first-first and first-second gate electrodes may overlap the first-first and first-second channel regions CH1-1a and CH1-2a in the plan view (i.e., along the third direction DR3), respectively and the fifth-first and fifth-second gate electrodes may overlap the fifth-first and fifth-second channel regions CH1-1b and CH1-2b in the plan view (i.e., along the third direction DR3), respectively.

In an embodiment, the first-first gate electrode and the first-second gate electrode may be configured as a single body, and the fifth-first gate electrode and the fifth-second gate electrode may be configured as a single body. That is, the first-first gate electrode and the first-second gate electrode may configure one first gate electrode GE1a, and fifth-first gate electrode and the fifth-second gate electrode may configure one fifth gate electrode GE1b.

In an embodiment, the first gate electrode GE1a may be disposed in the first and second pixel circuit areas PCAa and PCAb, and the fifth gate electrode GE1b may be disposed in the first and second pixel circuit areas PCAa and PCAb.

In an embodiment, the first gate electrode GE1a may have an L-shape in the plan view, and the fifth gate electrode GE1b may have an L-shape rotated 180 degrees in the plan view. However, embodiments are not necessarily limited thereto.

In an embodiment, the transistor array TA may further include a first connection pattern CNPa connecting the drain region DR1-1a of the first-first active portion A1-1a and the source region SR1-2a of the first-second active part A1-2a, and a second connection pattern CNPb connecting the drain region DR1-1b of the fifth-first active portion A1-1b and the source region SR1-2b of the fifth-second active portion A1-2b. Accordingly, the first-first and first-second driving transistors T1-1a and T1-2a may be electrically connected to each other, and the second-first and second-second driving transistors T1-1b and T1-2b may be electrically connected to each other.

FIG. 14 is a layout view illustrating another example of a first pixel driving circuit part and a second pixel driving circuit part included in the transistor array of FIG. 5.

Hereinafter, the first and second pixel driving circuit parts PCa and PCb described with reference to FIG. 14 may be substantially the same as or similar to the first and second pixel driving circuit parts PCa and PCb described with reference to FIG. 13, except for the structures of the gate electrodes of the first and second driving transistors T1a and T1b. Therefore, redundant descriptions will be omitted or simplified.

Referring to FIG. 14, the first-first driving transistor T1-1a, the first-second driving transistor T1-2a, the second-first driving transistor T1-1b, and the second-second driving transistor T1-2b may include the first-first active portion A1-1a, the first-second active portion A1-2a, the fifth-first active portion A1-1b, and the fifth-second active portion A1-2b of the substrate SUB spaced apart from each other, respectively.

The first-first driving transistor T1-1a and the first-second driving transistor T1-2a may further include a first-first gate electrode GE1-1a and a first-second gate electrode GE1-2a, respectively, and the second-first driving transistor T1-1b and the second-second driving transistor T1-2b may further include a fifth-first gate electrode GE1-1b and a fifth-second gate electrode GE1-2b, respectively.

In an embodiment, the first-first gate electrode GE1-1a and the first-second gate electrode GE1-2a may be spaced apart from each other, and the fifth-first gate electrode GE1-1b and the fifth-second gate electrode GE1-2b may be spaced apart from each other.

The first-first gate electrode GE1-1a and the first-second gate electrode GE1-2a may overlap the first-first channel region CH1-1a and the first-second channel region CH1-2a in the plan view (i.e., along the third direction DR3), respectively and the fifth-first gate electrode GE1-1b and the fifth-second gate electrode GE1-2b may overlap the fifth-first channel region CH1-1b and the fifth-second channel region CH1-2b in the plan view (i.e., along the third direction DR3), respectively.

In an embodiment, the first-first gate electrode GE1-1a may be disposed in the first pixel circuit area PCAa, the fifth-first gate electrode GE1-1b may be disposed in the second pixel circuit area PCAb, and each of the first-second gate electrode GE1-2a and the fifth-second gate electrode GE1-2b may be disposed in the first and second pixel circuit areas PCAa and PCAb.

In an embodiment, the transistor array TA may further include a first gate connection pattern GCPa connecting the first-first gate electrode GE1-1a and the first-second gate electrode GE1-2a, and a second gate connection pattern GCPb connecting the fifth-first gate electrode GE1-1band the fifth-second gate electrode GE1-2b.

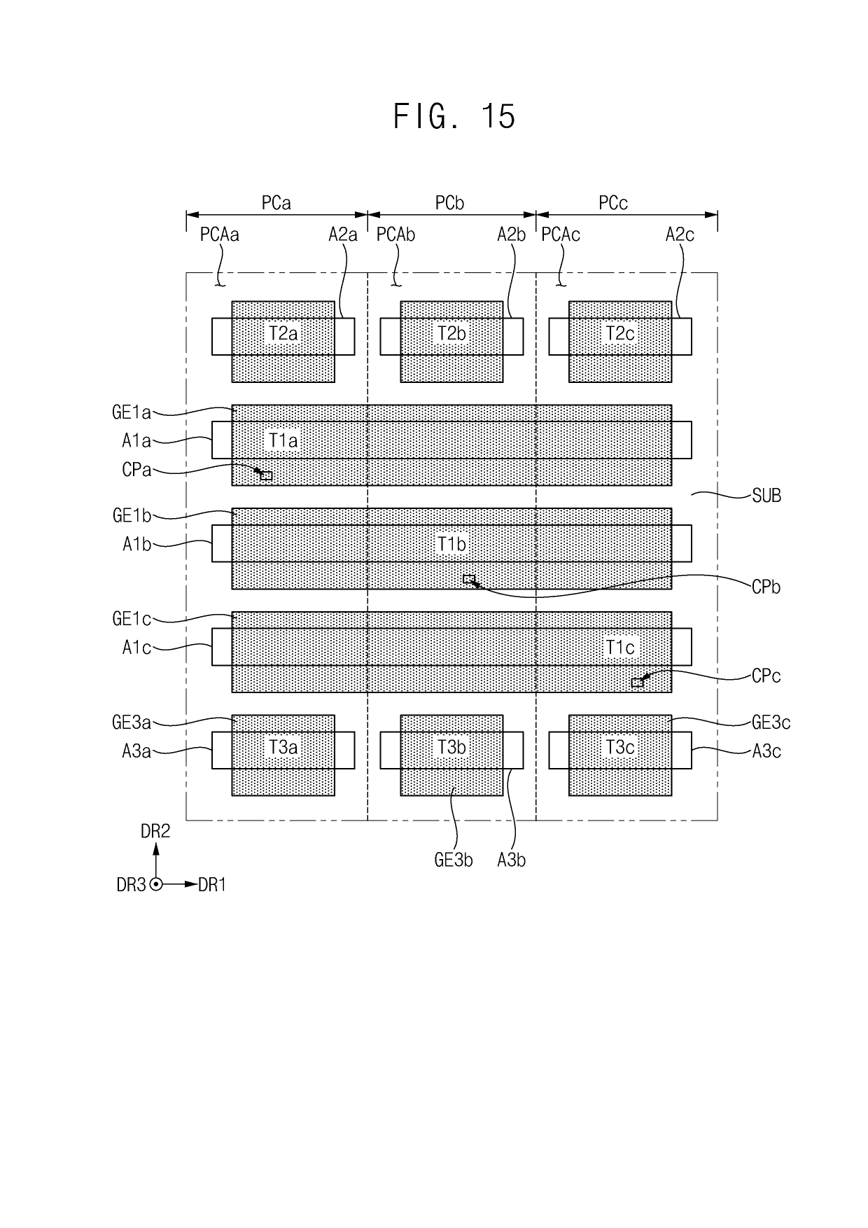

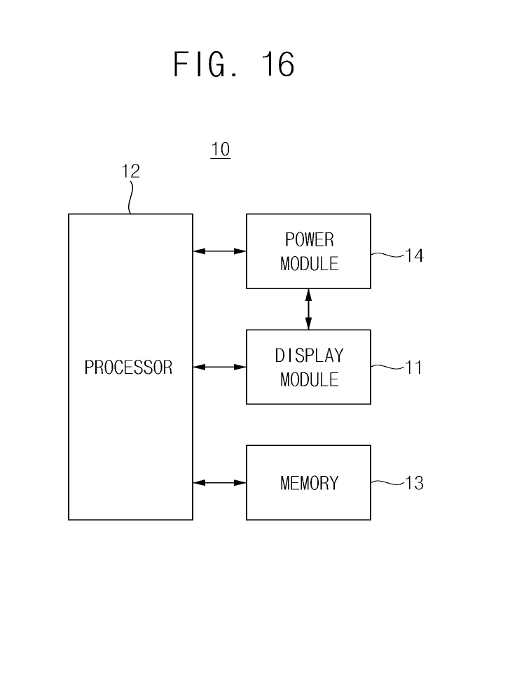

FIG. 15 is a layout view illustrating another example of the first, second, and third pixel driving circuit parts included in the transistor array of FIG. 5.

Hereinafter, the first, second, and third pixel driving circuit parts PCa, PCb, and PCc described with reference to FIG. 15 may be substantially the same as or similar to the first, second, and third pixel driving circuit parts PCa, PCb, and PCc described with reference to FIG. 10, except that the first, second, and third initialization transistors T4a, T4b, and T4c are omitted. Therefore, redundant descriptions will be omitted or simplified.

In addition, the following descriptions of the first, second, and third pixel driving circuit parts PCa, PCb, and PCc may substantially equally applied to the fourth, fifth, and sixth pixel driving circuit parts PCa’, PCb’, and PCc’ in FIG. 5.

Referring to FIG. 15, the first data writing transistor T2a, the first driving transistor T1a, and the first emission control transistor T3a may be sequentially disposed along the direction opposite to the second direction DR2. However, embodiments are not necessarily limited thereto, and the positions of the transistors disposed in the first pixel circuit area PCAa may be interchanged with each other. The arrangement order of the transistors included in each of the second pixel driving circuit part PCb and the third pixel driving circuit part PCc in the direction opposite to the second direction DR2 may be the same as the arrangement order of the transistors included in the first pixel driving circuit part PCa in the direction opposite to the second direction DR2.

The first, second, and third data writing transistors T2a, T2b, and T2c may be sequentially disposed along the first direction DR1, and the first, second, and third emission control transistors T3a, T3b, and T3c may be sequentially disposed along the first direction DR1.

In an embodiment, the second driving transistor T1b may be adjacent to the first driving transistor T1a in the direction opposite to the second direction DR2, and the third driving transistor T1c may be adjacent to the second driving transistor T1b in the direction opposite to the second direction DR2. Specifically, the first driving transistor T1a, the second driving transistor T1b, and the third driving transistor T1c may be disposed in different rows parallel to the first direction DR1. However, embodiments are not necessarily limited thereto, and the positions of the first driving transistor T1a, the second driving transistor T1b, and the third driving transistor T1c may be interchanged with each other.

In an embodiment, each of the first driving transistor T1a, the second driving transistor T1b, and the third driving transistor T1c may be disposed in the first, second, and third pixel circuit areas PCAa, PCAb, and PCA.

The third pixel driving circuit part PCc may correspond to the pixel driving circuit part PC’ in FIG. 11. That is, the third driving transistor T1c may correspond to the first transistor T1 in FIG. 11, the third data writing transistor T2c may correspond to the second transistor T2 in FIG. 1, and the third emission control transistor T3c may correspond to the third transistor T3 in FIG. 11.

Referring again to FIGS. 5 to 15, in the display device DD according to embodiments, two driving transistors of two pixel driving circuit parts respectively disposed in a first second pixel circuit area and a second pixel circuit area adjacent to each other may be disposed in both the first pixel circuit area and the second pixel circuit area. Alternatively, three driving transistors of three pixel driving circuit parts respectively disposed in a first pixel circuit area, a second pixel circuit area, and a third pixel circuit area adjacent to each other may be disposed in all of the first, second, and third pixel circuit areas. In this case, each of the driving transistors may have a sufficiently long channel length. Accordingly, the driving transistors may have a structure robust to variation. Accordingly, the display device DD may implement high resolution and display quality may be improved.

FIG. 16 is a block diagram illustrating an electronic device according to embodiments.

Referring to FIG. 16, an electronic device 10 according to embodiments may include a display module 11, a processor 12, a memory 13, and a power module (e.g., power circuitry) 14.

A display device (e.g., the display device DD of FIG. 1) according to embodiments may be applied to various electronic devices. The electronic device 10 may include the display device described above, and may further include a module or device having additional functions in addition to the display device.

The processor 12 may include at least one of a central processing unit (CPU), an application processor (AP), a graphic processing unit (GPU), a communication processor (CP), an image signal processor (ISP) and a controller.

The memory 13 may store data information necessary for the operation of the processor 12 or the display module 11. In case that the processor 12 executes the application stored in the memory 13, an input image data (e.g., IDAT in FIG. 2) and/or a control signal (e.g., CTRL in FIG. 2) may be transmitted to the display module 11, and the display module 11 may process the received signal and output image information through a display screen.

The power module 14 may include a power supply, such as a power adapter or a battery device, and a power conversion circuit which converts the power supplied by the power supply to generate power required for the operation of the electronic device 10.

At least one of each component of the electronic device 10 described above may be included in the display device according to the above-described embodiments. In addition, some of the individual modules functionally included in one module may be included in the display device, and other portions may be provided separately from the display device. For example, the display device may include the display module 11, and the processor 12, the memory 13, and the power module 14 may be provided in the form of other devices within the electronic device 10 other than the display device.

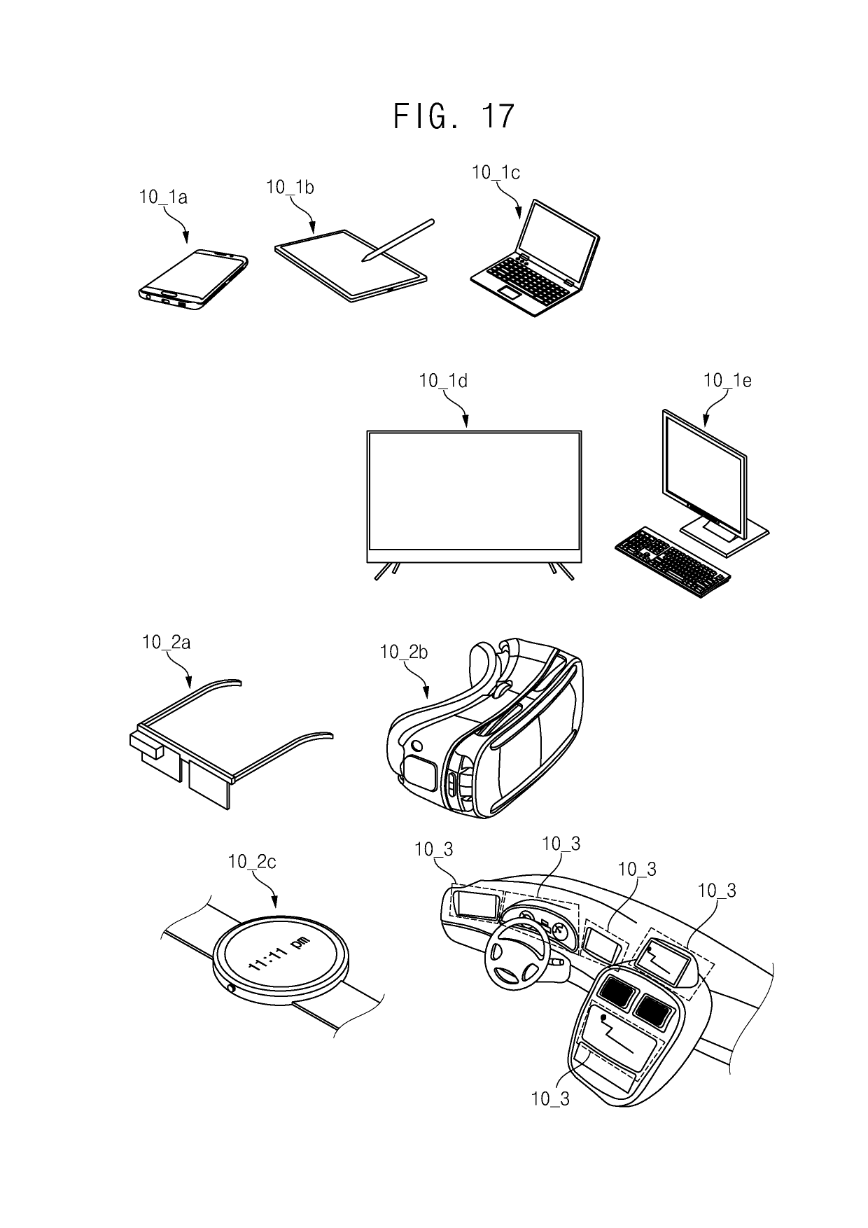

FIG. 17 is a schematic diagram illustrating an electronic device according to various embodiments.

Referring to FIGS. 16 and 17, various electronic devices 10 to which display devices according to embodiments are applied may include not only image display electronic devices such as a smartphone 10_1a, a tablet PC 100_1b, a laptop 10_1c, a TV 10_1d, and a desktop monitor 10_1e, but also wearable electronic devices including display modules, such as smart glasses 10_2a, a head-mounted display 10_2b, and a smart watch 10_2c, automotive electronic devices 10_3 including display modules, such as a dashboard of a car, a center fascia, a Center Information Display (CID) disposed on a dashboard, and a room mirror display, or the like.

As described above, while the present disclosure has been explained with reference to exemplary embodiments, it will be understood by those of ordinary skill in the art that various modifications and changes can be made thereto without departing from the spirit and scope of the invention as defined in the following claims.

The present disclosure may be applied to a process for manufacturing various display devices which can be equipped with a display device. For example, the present disclosure may be applied to high-resolution smartphones, mobile phones, smart pads, smart watches, tablet PCs, vehicle navigation systems, televisions, computer monitors, and notebook computers.

What is claimed is:

1. A display device comprising:
a substrate comprising a first pixel circuit area and a second pixel circuit area, wherein the second pixel circuit area is adjacent to the first pixel circuit area in a first direction;
a first driving transistor of a first pixel driving circuit part, wherein the first driving transistor is provided in both of the first and second pixel circuit areas;
a second driving transistor of a second pixel driving circuit part, wherein the second driving transistor provided in both of the first and second pixel circuit areas, and is adjacent to the first driving transistor in a second direction intersecting the first direction;
a first light-emitting element connected to the first pixel driving circuit part and provided in a first light-emitting area; and
a second light-emitting element connected to the second pixel driving circuit part and provided in a second light-emitting area configured to emit light of a different color from the first light-emitting area.

2. The display device of claim 1, wherein at least one of the first and second driving transistors comprises:
an active portion comprising a source region, a drain region, and a channel region between the source region and the drain region of the substrate; and
a gate electrode overlapping the channel region of the active portion in a plan view, and
wherein the active portion and the gate electrode of the at least one of the first and second driving transistors are provided in both of the first and second pixel circuit areas.

3. The display device of claim 1, further comprising:
a first data writing transistor of the first pixel driving circuit part, wherein the first data writing transistor is provided in the first pixel circuit area, is connected to the first driving transistor, and receives a first data voltage in response to a first gate signal;
a first emission control transistor of the first pixel driving circuit part, wherein the first emission control transistor is provided in the first pixel circuit area, is connected to the first driving transistor, and receives a driving voltage in response to an emission control signal; and
a first initialization transistor of the first pixel driving circuit part, wherein the first initialization transistor is provided in the first pixel circuit area, is connected to the first driving transistor, and receives a first initialization voltage in response to a second gate signal,
wherein the first data writing transistor, the first emission control transistor, the first driving transistor, and the first initialization transistor are sequentially provided along the second direction.

4. The display device of claim 3, further comprising:
a second data writing transistor of the second pixel driving circuit part, wherein the second data writing transistor is provided in the second pixel circuit area, is connected to the second driving transistor, and receives a second data voltage in response to the first gate signal;
a second emission control transistor of the first pixel driving circuit part, wherein the second emission control transistor is provided in the first pixel circuit area, is connected to the second driving transistor, and receives the driving voltage in response to the emission control signal; and
a second initialization transistor of the second pixel driving circuit part, wherein the second initialization transistor is provided in the second pixel circuit area, is connected to the second driving transistor, and receives a second initialization voltage in response to the second gate signal,
wherein the second data writing transistor, the second emission control transistor, the second driving transistor, and the second initialization transistor are sequentially provided along the second direction.

5. The display device of claim 1, wherein the substrate further comprises a third pixel circuit area adjacent to the second pixel circuit area in the first direction, and a fourth pixel circuit area adjacent to the third pixel circuit area in the first direction, and
wherein the display device further comprises:
a third driving transistor of a third pixel driving circuit part, wherein the third driving transistor is provided in both of the third and fourth pixel circuit areas;
a fourth driving transistor of a fourth pixel driving circuit part, wherein the fourth driving transistor is provided in both of the third and fourth pixel circuit areas, and is adjacent to the third driving transistor in the second direction;
a third light-emitting element connected to the third pixel driving circuit part and overlapping a third light-emitting area; and
a fourth light-emitting element connected to the fourth pixel driving circuit part and overlapping a fourth light-emitting area configured to emit light of a different color from the third light-emitting area.

6. The display device of claim 5, wherein the third and fourth driving transistors are offset, respectively, from the first and second pixel circuit areas along the first and second directions.

7. The display device of claim 5, wherein the third driving transistor and the first driving transistor are positioned in a N-th row (where N is natural number) parallel to the first direction, and
wherein the fourth driving transistor and the second driving transistor are positioned in a (N+1)-th row parallel to the first direction and adjacent to the N-th row in the second direction.

8. The display device of claim 5, wherein the fourth driving transistor and the first driving transistor are positioned in a N-th row (where N is natural number) parallel to the first direction, and
wherein the third driving transistor and the second driving transistor are positioned in a (N+1)-th row parallel to the first direction and adjacent to the N-th row in the second direction.

9. The display device of claim 1, wherein the substrate further comprises a third pixel circuit area adjacent to the second pixel circuit area in the first direction,
wherein the display device further comprises:
a third driving transistor of a third pixel driving circuit part, wherein the third driving transistor is provided in each of the first, second, and third pixel circuit areas, and is adjacent to the second driving transistor in the second direction; and
a third light-emitting element connected to the third pixel driving circuit part and overlapping a third light-emitting area configured to emit light of a different color from the first and second light-emitting areas, and
wherein at least one of the first driving transistor and the second driving transistor extends from the first and second pixel circuit areas to the third pixel circuit area.

10. The display device of claim 1, wherein the first driving transistor comprises:
a first-first driving transistor provided in the first pixel circuit area; and
a first-second driving transistor provided in both of the first and second pixel circuit areas, wherein the first-second driving transistor is connected to the first-first driving transistor, and is adjacent to the first-first driving transistor in the second direction, and
wherein the second driving transistor comprises:
a second-first driving transistor provided in the second pixel circuit area; and
a second-second driving transistor provided both of in the first and second pixel circuit areas, wherein the second-second driving transistor is connected to the second-first driving transistor, and is adjacent to the second-first driving transistor in a direction opposite to the second direction.

11. The display device of claim 10, wherein the first-first driving transistor comprises a first-first active portion of the substrate provided in the first pixel circuit area and a first-first gate electrode overlapping a channel region of the first-first active portion,
wherein the first-second driving transistor comprises a first-second active portion of the substrate provided in both of the first and second pixel circuit areas and a first-second gate electrode overlapping a channel region of the first-second active portion,
wherein the second-first driving transistor comprises a second-first active portion of the substrate provided in the second pixel circuit area and a second-first gate electrode overlapping a channel region of the second-first active portion, and
wherein the second-second driving transistor comprises a second-second active portion of the substrate provided in both of the first and second pixel circuit areas and a second-second gate electrode overlapping a channel region of the second-second active portion.

12. The display device of claim 11, further comprising:
a first connection pattern connecting a drain region of the first-first active portion and a source region of the first-second active portion; and
a second connection pattern connecting a drain region of the second-first active portion and a source region of the second-second active portion.

13. The display device of claim 12, wherein the first-first gate electrode and the first-second gate electrode are configured as a single body, and
wherein the second-first gate electrode and the second-second gate electrode are configured as a single body.

14. The display device of claim 12, further comprising:
a first gate connection pattern connecting the first-first gate electrode and the first-second gate electrode; and
a second gate connection pattern connecting the second-first gate electrode and the second-second gate electrode.

15. The display device of claim 10, further comprising:
a first data writing transistor of the first pixel driving circuit part, wherein the first data writing transistor is provided in the first pixel circuit area, is connected to the first driving transistor, and receives a first data voltage in response to a gate signal; and
a first emission control transistor of the first pixel driving circuit part, wherein the first emission control transistor is provided in the first pixel circuit area, is connected to the first driving transistor, and receives a driving voltage in response to an emission control signal,
wherein the first data writing transistor, the first driving transistor, and the first emission control transistor are sequentially provided along the second direction.

16. The display device of claim 15, further comprising:
a second data writing transistor of the second pixel driving circuit part, wherein the second data writing transistor is provided in the second pixel circuit area, is connected to the second driving transistor, and receives a second data voltage in response to the gate signal; and
a second emission control transistor of the second pixel driving circuit part, wherein the second emission control transistor is provided in the second pixel circuit area, is connected to the second driving transistor, and receives the driving voltage in response to the emission control signal,
wherein the second data writing transistor, the second driving transistor, and the second emission control transistor are sequentially provided along the second direction.

17. The display device of claim 1, wherein the substrate comprises a silicon wafer substrate.

18. The display device of claim 1, wherein the first and second driving transistors are p-type metal-oxide-semiconductor (PMOS) transistors.

19. An electronic device comprising:
a display panel comprising:
a substrate comprising a first pixel circuit area and a second pixel circuit area, wherein the second pixel circuit area is and adjacent to the first pixel circuit area in a first direction;
a first driving transistor of a first pixel driving circuit part, wherein the first driving transistor is provided in both of the first and second pixel circuit areas;
a second driving transistor of a second pixel driving circuit part, wherein the second driving transistor is provided in both of the first and second pixel circuit areas, and is adjacent to the first driving transistor in a second direction intersecting the first direction;
a first light-emitting element connected to the first pixel driving circuit part and provided in a first light-emitting area; and
a second light-emitting element connected to the second pixel driving circuit part and provided in a second light-emitting area configured to emit light of a different color from the first light-emitting area;
a controller configured to control an operation of the display panel based on an input image data and a control signal; and
a processor configured to provide the input image data and the control signal to the controller.

20. The electronic device of claim 19, wherein at least one of the first and second driving transistors comprises:
an active portion comprising a source region, a drain region, and a channel region between the source region and the drain region of the substrate; and
a gate electrode overlapping the channel region of the active portion in a plan view, and
wherein the active portion and the gate electrode of the at least one of the first and second driving transistors are provided in both of the first and second pixel circuit areas.
